(19) United States
(12) Patent Application Publication
(10) Pub. No.: US 2020/0105670 A1
(43) Pub. Date: Apr. 2, 2020

(54) MIDDLE-OF-LINE (MOL) COMPLEMENTARY POWER RAIL(S) IN INTEGRATED CIRCUITS (ICs) FOR REDUCED SEMICONDUCTOR DEVICE RESISTANCE

(71) Applicant: QUALCOMM Incorporated, San Diego, CA (US)

(72) Inventors: John Jianhong Zhu, San Diego, CA (US); Haining Yang, San Diego, CA (US); Kern Rim, San Diego, CA (US); Ye Lu, San Diego, CA (US)

(21) Appl. No.: 16/146,843

(22) Filed: Sep. 28, 2018

(51) Int. Cl. H01L 23/528; H01L 27/02; H01L 27/092

(52) U.S. Cl. CPC H01L 23/5286; H01L 2027/11881; H01L 27/0924; H01L 27/0207

(57) ABSTRACT

Middle-of-line (MOL) complementary power rail(s) in integrated circuits (ICs) for reduced semiconductor device resistance, and related methods are disclosed. In exemplary aspects, to reduce or mitigate an increase in resistance in the cell power rails in the IC, a complementary power rail(s) is formed in a MOL layer(s) of the IC and coupled to cell power rail(s) formed in a metal layer in a front-end-of-line (FEOL) layer in the IC. In exemplary aspects, the MOL layer(s) in which the complementary power rail is formed is in a layer below the metal layer in the FEOL layer in which the cell power rail is formed. The complementary power rail has the effect of reducing the resistance of the cell power rail, and thus has the effect of reducing the resistance of FET(s) coupled to the cell power rail thereby increasing performance.

### BACKGROUND

### I. Field of the Disclosure

The technology of the disclosure relates generally to semiconductor devices, and more specifically, to parasitic resistance of conductors realized in standard cell architecture circuits.

### II. Background

Transistors are essential components in modern electronic devices, and large numbers of transistors are employed in integrated circuits (ICs) therein. For example, components such as central processing units (CPUs) and memory systems each employ a large quantity of transistors for logic circuits and memory devices. For example, FIG. 1 illustrates a conventional complementary metal-oxide semiconductor (CMOS) Fin Field-Effect Transistor (FET) 100 (“FinFET 100”) as an example of a transistor. A FinFET includes a gate material wrapped around at least a portion of a channel structure to provide better gate control over an active channel therein. Better gate control provides reduced current leakage and increased threshold voltage as compared to a planar transistor of a similar footprint.

In this regard, FIG. 1 illustrates a conventional MOS FinFET 100 (“FinFET 100”) as an example. The FinFET 100 includes a substrate 102 and a fin 104 made of a semiconductor material disposed above the substrate 102. An oxide layer 106 is included on either side of the fin 104. The FinFET 100 includes a “wrap-around” gate 108 disposed on the substrate 102 and over the fin 104. A source 110 and a drain 112 are formed in the fin 104 on opposing sides of the gate 108 to provide the source 110 and the drain 112 for the FinFET 100. Metal contacts (not shown) are disposed in contact with the source 110 and the drain 112 to provide respective source and drain contacts. The fin 104 serves as a conduction channel 114 between the source 110 and the drain 112. The wrap-around structure of the gate 108 provides better electrostatic control over the conduction channel 114, and thus helps reduce the leakage current and overcomes other SCEs.

For example, FIG. 2A illustrates a top view of a circuit cell 200 that can be used to form a circuit 202 that includes FETs, such as the FinFET 100 in FIG. 1. The circuit 202 can be included in an IC. FIG. 2B is a cross-sectional side view across the A₁-A₁′ line in the IC 202 in FIG. 2A. The circuit cell 200 includes gate G(3) disposed in a first direction 204 on a Y-axis with a defined gate pitch Gp. The circuit 202 includes a first power rail 206(1) configured to be coupled to a supply voltage. The first power rail 206(1) is disposed in a second direction 208 in an X-axis substantially orthogonal to the first direction 204 in a metal layer 210 (e.g., a metal one (M1) metal layer) that is typically formed in a middle-of-line (MOL) fabrication process of the circuit 202. Additionally, the circuit 202 includes a second power rail 206(2) also disposed in the second direction 208 in the metal layer 210. For example, the second power rail 206(2) may be configured to be coupled to a negative voltage or a ground node. The circuit 202 also includes diffusion regions 212P, 212N of P-type and N-type doped semiconductor materials, respectively, for forming active devices that include semiconducting materials, such as transistors. The circuit 202 also includes Fins 214(1)-214(3) for forming semiconductor channels of FinFETs disposed in the second direction 208 between the first and second power rails 206(1), 206(2).

As further shown in FIG. 2A, a P-type FET FinFET (“PFET”) 214P is formed in the P-type diffusion region 212P by forming a source S_{PFET} and a drain D_{PFET} in/on the Fin 214(1) on opposite sides of the gate G(2). An active gate G_{A} for the PFET 214P is formed in the gate G(2). Similarly, an N-type FET FinFET (“NFET”) 214N is formed in the N-type diffusion region 212N by forming a source S_{NFET} and a drain D_{NFET} in/on the Fin 214(3) on opposite sides of the gate G(2). The active gate G_{A} for the PFET 214P is also the active gate G_{A} for the NFET 214N, meaning the gates of the PFET 214P and NFET 214N are coupled together in this example. To provide connectivity to the active gate G_{A}, sources S_{NFET}, S_{PFET} and drains D_{NFET}, D_{PFET} Of the PFET 214P and NFET 214N, metal contacts 216(1)-216(5) of a metal material are formed above and in contact with the respective source S_{PFET} and drain D_{PFET} of the PFET 214P, the active gate G_{A}, and the source and drain S_{NFET}, D_{NFET} of the NFET 214N as shown in FIGS. 2A and 2B. Metal contact lines 218(1)-218(5) are formed above and directly in contact with the respective metal contacts 216(1)-216(5), which may then be planarized. Vertical interconnect accesses (vias) 220(1)-220(5) are formed above and in contact with the respective metal contact lines 218(1)-218(5) to provide connectivity to metal interconnect lines 222(1)-222(3) in the metal layer 210. In this example, as shown in FIG. 2A, the source S_{PFET} of the PFET 214P and the source of the NFET 214N are coupled to the respective first and second power rails 206(1), 206(2) through the metal contact lines 218(1), 218(4).

One substantial factor that contributes to the performance of the circuit 202 in is the resistance of the first and second power rails 206(1), 206(2), and in particular the first power rail 206(1) that receives a supply voltage. The resistance of the first and second power rails 206(1), 206(2) contributes to the overall resistance of the PFET 214P and NFET 214N. In digital circuits in particular, as a particular stage switches, a high resistance causes a large current (I) resistance (R) (IR) drop, thereby reducing gate overdrive, which in turn reduces switching speed (i.e., increases delay). The first and second power rails 206(1), 206(2) having a lower IR is also important, because the vias (not shown) formed above the first and second power rails 206(1), 206(2) to provide interconnectivity may have a larger pitch for compact placement of multiple circuit 202 when circuits 202 are abutted to each other, thus increasing via resistance.

However, the trend has been to scale down the size of a circuit cell used to form circuits, such as the circuit cell 200 in FIGS. 2A and 2B. This causes the width of the power rails, such as width W₁ of the first power rail 206(1) in FIG. 2A, to be reduced in the height or Y-axis direction (first direction 204), thus increasing the resistance of the power rails. Additional power rails could be provided in higher metal layers above the first and second power rails 206(1), 206(2) to mitigate an increase in resistance due to scaling, but at the expense of increased area in the vertical, Z-axis direction.

### SUMMARY OF THE DISCLOSURE

Aspects disclosed herein include middle-of-line (MOL) complementary power rail(s) in integrated circuits (ICs) for reduced semiconductor device resistance. Related methods are also disclosed. For example, the IC may be realized in a cell circuit that is laid out according to a circuit cell architecture, such as a standard cell for complementary metal oxide semiconductor (CMOS) circuits. In exemplary aspects an integrated circuit (IC) is provided that includes a diffusion region(s) formed in a substrate. Semiconductor devices, such as field-effect transistors (FETs), are formed in in the diffusion region(s) in a back-end-of-line (BEOL) layer(s) in the IC. Metal contacts are formed in contact with gates, sources, and drains of FETs fabricated in the IC to provide connectivity to the FET. Metal contact lines can be formed in contact with the metal contacts to provide routing of connections to the FETs. Vias are formed in contact with the metal contact lines to extend connectivity from the FETs to metal lines in upper metal interconnect layers including cell power rails. Thus, the resistance of cell power rails in the IC contributes to the overall resistance of the FETs formed therein. A high resistance causes a large current (I) resistance (R) (IR) drop, thereby reducing FET gate overdrive, which in turn reduces switching speed (i.e., increases delay). As node size is scaled down, the size of the power rails in an IC may also be reduced, thereby increasing resistance of the power rail and FETs coupled to the power rail in an undesired manner. Thus, in exemplary aspects disclosed herein, to reduce or mitigate an increase in resistance in the cell power rails in the IC, a complementary power rail(s) is formed in a MOL layer(s) of the IC and coupled to cell power rail(s) formed in a metal layer in a front-end-of-line (FEOL) layer in the IC. In examples disclosed herein, the MOL layer(s) in which the complementary power rail is formed is in a layer below the metal layer in the FEOL layer in which the cell power rail is formed. The complementary power rail has the effect of reducing the resistance of the cell power rail, and thus has the effect of reducing the resistance of FET(s) coupled to the cell power rail thereby increasing performance. This is opposed to, for example, forming additional metal lines in higher metal layers above the metal layer of the cell power rail in the FEOL layer(s) of the IC, which can increase the vertical height of the IC and thus increase circuit cell area in an undesired manner.

In one exemplary aspect, a complementary power rail is formed as an elongated metal line in a MOL layer in the IC below the metal layer of the cell power rail in a FEOL layer in the IC and coupled together with parallel arranged vias to reduce resistance. In another exemplary aspect, the complementary power rail is formed in a MOL layer in the IC as an elongated via extending along a longitudinal axis parallel to the longitudinal axis of the cell power rail, with the cell power rail fabricated above and in contact with the elongated via to reduce resistance. In another exemplary aspect, the complementary power rail is formed in a MOL layer in the IC as an elongated via and an elongated metal line. The elongated via and elongated metal line both extend along a longitudinal axis parallel to the longitudinal axis of the cell power rail, with the elongated via fabricated above and in contact with the elongated metal line, and the cell power rail fabricated above and in contact with the elongated via to reduce resistance. In another exemplary aspect, the complementary power rail is formed as an elongated metal line in a MOL layer in the IC and coupled to the cell power rail with parallel arranged vias and including at least one elongated via to reduce resistance.

In other exemplary aspects, to further reduce resistance or mitigate an increase in resistance in the IC, such as a result of scaling down the size of cell circuits in the IC, the signal contacts or lines (e.g., gate, source, and/or drain contacts of FETs and/or local metal routing lines) formed in the circuit cell can be formed from a metal that requires a thinner barrier layer to reduce or prevent metal diffusion into an interlayer dielectric (ILD). For example, Copper has a low resistivity, but requires a thicker barrier layer to prevent diffusion. Thus, use of Copper may be advantageous for power rails in the IC to keep resistance lower. However, use of Copper as signal contacts or lines in scaled down ICs may increase resistance of signal contacts or lines, because a thicker barrier layer may still be required to prevent diffusion. Thus, to avoid having to trade off either use of a lower resistivity material, such as Copper, at the expense of a thicker barrier layer which may increase signal contact and/or signal line resistance, or using a higher resistivity material that is less susceptive to diffusion and thus may allow use of a thinner barrier layer, a lower resistivity material, such as Copper, is used for the power rails, whereas a higher resistivity material, such as Ruthenium or Cobalt, is used for signal contacts and/or signal lines. The reduced barrier layer thickness for the signal contacts and/or signal lines allowing a larger volume of a higher resistivity metal may result in a lower signal contact/line resistance than a smaller volume of a lower resistivity metal due to a thicker barrier layer.

In this regard, in one exemplary aspect, an IC is provided. The IC comprises a FEOL layer. The FEOL layer comprises a diffusion region in a substrate as well as at least one semiconductor channel structure in the diffusion region. The FEOL layer also comprises at least one semiconductor channel structure having a first longitudinal axis in a first direction. The FEOL layer also comprises a plurality of conducting gates disposed above the substrate, the plurality of gates each having a second longitudinal axis in a second direction substantially orthogonal to the first longitudinal axis. The FEOL layer also comprises a FET, comprising a semiconductor channel in a semiconductor channel structure among the at least one semiconductor channel structures, an active gate in a portion of a conducting gate among the plurality of conducting gates adjacent to the semiconductor channel, a source in a first end portion of the semiconductor channel, and a drain in a second end portion of the semiconductor channel. The FEOL layer also comprises a signal metal contact disposed above and in contact with one of the first active gate, the source, and the drain. The IC also comprises a BEOL layer disposed above the FEOL layer, the BEOL layer comprising a metal interconnect layer comprising a cell power rail disposed in a first vertical access area and coupled to a supply voltage node configured to receive a supply voltage. The IC also comprises a MOL layer disposed between the FEOL layer and the BEOL layer. The MOL layer comprises a power rail metal contact line in contact with the signal metal contact. The MOL layer also comprises a complementary power rail disposed in a second vertical access area. The complementary power rail is coupled to the power rail metal contact line and the cell power rail.

In another exemplary aspect, an IC is provided. The IC comprises a FEOL layer. The FEOL layer comprises a means for providing a diffusion in a substrate. The FEOL layer also comprises a means for providing a semiconducting conduction path in the means for providing a diffusion. The FEOL layer also comprises a plurality of means for controlling the means for providing the semiconducting conduction path. The FEOL layer also comprises a FET. The FET comprises a semiconductor channel in in the means for providing a semiconducting conduction path, an active gate in a portion of the means for controlling the means for providing the semiconducting conduction path adjacent to the semiconductor channel, a source in a first end portion of the semiconductor channel, and a drain in a second end portion of the semiconductor channel. The FEOL layer also comprises a means for providing a signal contact disposed above and in contact with one of the first active gate, the source, and the drain. The IC also comprises a BEOL layer disposed above the FEOL layer. The BEOL layer comprises a metal interconnect layer comprising a means for providing a cell power node disposed in a first vertical access area and coupled to a supply voltage node configured to receive a supply voltage. The IC also comprises a MOL layer disposed between the FEOL layer and the BEOL layer. The MOL layer comprises a means for providing a signal contact coupling in contact with the means for providing a signal contact, and a complementary means for providing a cell power node disposed in a second vertical access area. The MOL layer also comprises the complementary means for providing a cell power node coupled to the means for providing a signal contact coupling and the means for providing a cell power node.

In another exemplary aspect, a method of fabricating an IC is provided. The method comprises providing a FEOL layer comprising forming a diffusion region in a substrate, forming at least one semiconductor channel structure in the diffusion region, the at least one semiconductor channel structure having a first longitudinal axis in a first direction, and forming a plurality of conducting gates disposed above the substrate, the plurality of gates each having a second longitudinal axis in a second direction substantially orthogonal to the first longitudinal axis. The method also comprises forming a FET in the diffusion region comprising a semiconductor channel in a semiconductor channel structure among the at least one semiconductor channel structures, an active gate in a portion of a conducting gate among the plurality of conducting gates adjacent to the semiconductor channel, a source in a first end portion of the semiconductor channel, and a drain in a second end portion of the semiconductor channel. The method also comprises forming a signal metal contact disposed above and in contact with one of the first active gate, the source, and the drain. The method also comprises providing a BEOL layer disposed above the FEOL layer comprising forming a metal interconnect layer comprising forming a cell power rail disposed in a first vertical access area and coupled to a supply voltage node configured to receive a supply voltage. The method also comprises providing a MOL layer disposed between the FEOL layer and the BEOL layer, comprising forming a power rail metal contact line in contact with the signal metal contact, and forming a complementary power rail disposed in a second vertical access area, the complementary power rail coupled to the power rail metal contact line and the cell power rail.

### BRIEF DESCRIPTION OF THE FIGURES

FIG. 1 is a perspective view of an exemplary Fin Field-Effect Transistor (FET) (FinFET);

FIG. 2A is a top view of an exemplary integrated circuit (IC) fabricated according to a circuit cell and illustrating exemplary FETs and interconnections between the FETs and power rails:

FIG. 2B is a cross-sectional side view of the IC in FIG. 2A;

FIG. 3A is a top view of an exemplary IC that includes a middle-of-line (MOL) complementary power rail(s) coupled to a cell power rail(s) in the IC for reduced resistance, wherein the MOL complementary power rail is in the form of an elongated metal line(s) in a MOL layer in the IC coupled to a cell power rail with parallel arranged vertical interconnect accesses (vias);

FIG. 3B is a cross-sectional side view of the IC in FIG. 3A to further illustrate a complementary power rail coupled to the cell power rail;

FIG. 4A is a top view of an exemplary IC that includes a middle-of-line (MOL) complementary power rail(s) coupled to a cell power rail(s) in the IC for reduced resistance, wherein the MOL complementary power rail is in the form of an elongated via(s) extending in a longitudinal axis parallel to the longitudinal axis of the cell power rail, with the cell power rail fabricated above and in contact with the elongated via(s);

FIG. 4B is a cross-sectional side view of the IC in FIG. 4A to further illustrate a complementary power rail coupled to the cell power rail:

FIG. 5A is a top view of an exemplary IC that includes a middle-of-line (MOL) complementary power rail(s) coupled to a cell power rail(s) in the IC for reduced resistance, wherein the MOL complementary power rail is in the form of an elongated via(s) and an elongated metal line(s) both extending in a longitudinal axis parallel to the longitudinal axis of the cell power rail(s), with the elongated via fabricated above and in contact with the elongated metal line(s), and the cell power rail fabricated above and in contact with the elongated to reduce resistance;

FIG. 5B is a cross-sectional side view of the IC in FIG. 5A to further illustrate a complementary power rail coupled to the cell power rail:

FIG. 6A is a top view of an exemplary IC that includes a middle-of-line (MOL) complementary power rail(s) coupled to a cell power rail(s) in the IC for reduced resistance, wherein the MOL complementary power rail is in the form of an elongated metal line(s) coupled to a cell power rail(s) with parallel arranged vias and including at least one elongated via(s);

FIG. 6B is a cross-sectional side view of the IC in FIG. 6A to further illustrate a complementary power rail coupled to the cell power rail;

FIG. 7A is a side view of another exemplary IC illustrating local interconnect metal layers in MOL layers and global metal interconnect layers in front end-of-line (FEOL) layers above the local metal interconnect layers, with metal lines formed in the interconnect layers forming power rails and signal lines;

FIG. 7B is a top view of the IC in FIG. 7A illustrating power rails and signal lines formed in a MOL local interconnect metal layer of the IC;

FIG. 8 is a graph illustrating an exemplary plot of resistivity of Copper as a function of area;

FIG. 9 is a graph illustrating resistance per unit length (R/L) of Copper and Ruthenium as a function of trench area;

FIG. 10A is a side view of another exemplary IC illustrating local interconnect metal layers in MOL layers and global metal interconnect layers in FEOL layers above the local metal interconnect layers, wherein cell power rails of higher resistivity material encompassed by a thicker barrier layer to reduce or prevent diffusion and signal metal lines with a lower resistivity encompassed by a thinner barrier layer are formed in a MOL local interconnect metal layer(s);

FIG. 10B is a top view of the IC in FIG. 10A illustrating the power rails and signals lines formed in a MOL local interconnect metal layer of the IC;

FIGS. 11A-11G are side views of exemplary fabrication stages of fabricating the cell power rails of higher resistivity material encompassed by a thicker barrier layer and signal metal lines with a lower resistivity encompassed by a thinner barrier layer in local interconnect layers in MOL layers in an IC, which may be according to the exemplary process;

FIG. 12 is a side view of the IC fabricated as a result of the exemplary fabrication process illustrated in the exemplary fabrication stages in FIGS. 11A-1G, wherein the IC includes local interconnect metal layers in MOL layers and global metal interconnect layers in FEOL layers above the local metal interconnect layers, wherein cell power rails formed of higher resistivity material encompassed by a thicker barrier layer to reduce or prevent diffusion and signal metal lines with a lower resistivity encompassed by a thinner barrier layer are formed in a MOL local interconnect metal layer(s);

FIG. 13 is a block diagram of an exemplary processor-based system that can include an IC that includes a MOL complementary power rail(s) coupled to a cell power rail(s) in the IC for reduced resistance, including but not limited to the ICs 300, 400, 500, and 600, 1001, and 1201 in FIGS. 3A-6B, 10, and 12; and

FIG. 14 is a block diagram of an exemplary wireless communications device that includes radio frequency (RF) components formed from an IC that can include a MOL complementary power rail(s) coupled to a cell power rail(s) in the IC for reduced resistance, including but not limited to the ICs 300, 400, 500, 600, 1001, and 1201 in FIGS. 3A-6B, 10, and 12.

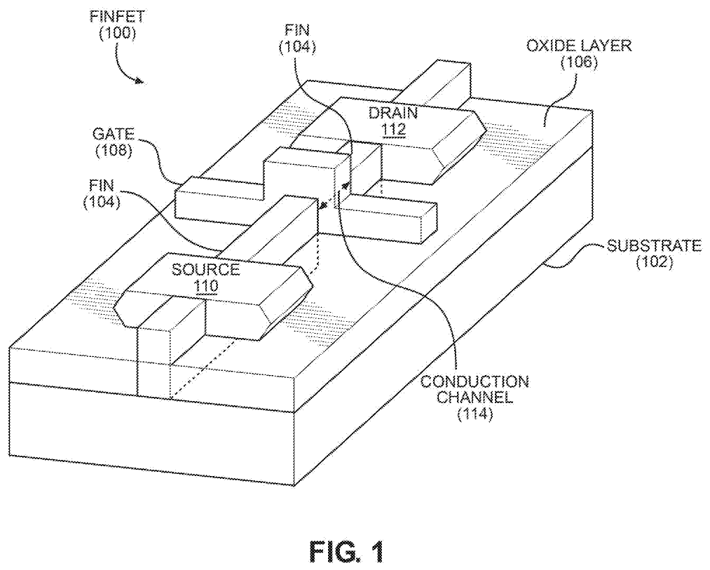

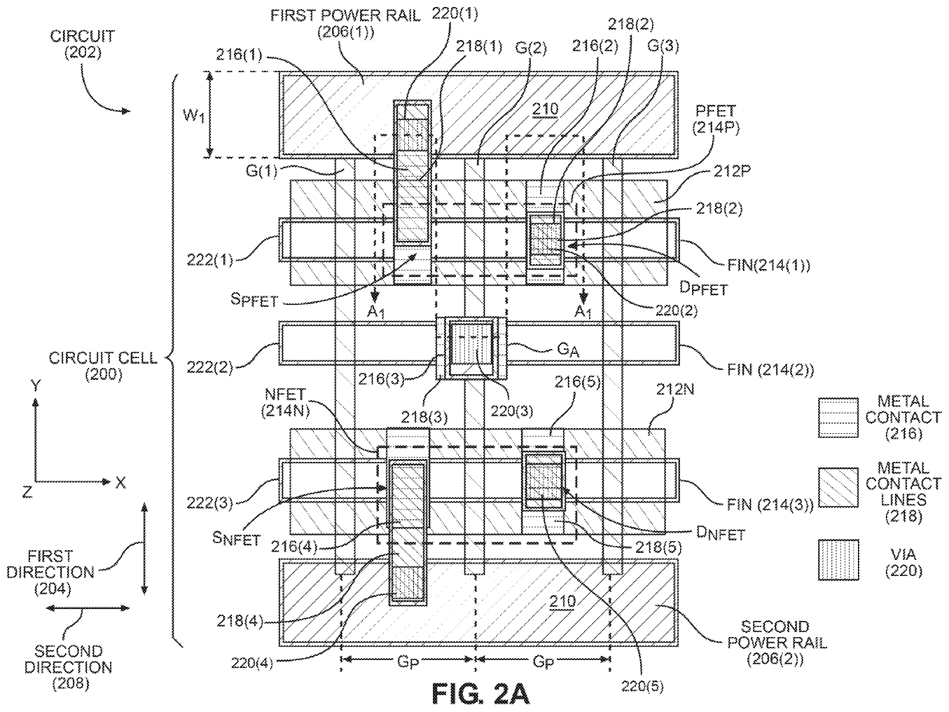

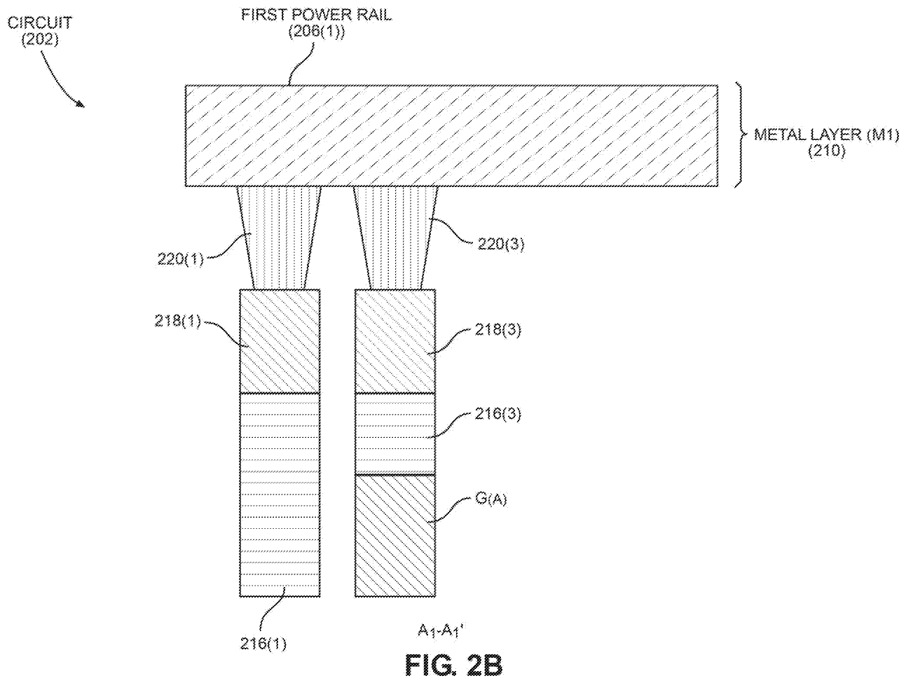

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include middle-of-line (MOL) complementary power rail(s) in integrated circuits (ICs) for reduced semiconductor device resistance. Related methods are also disclosed. For example, the IC may be realized in a cell circuit that is laid out according to a circuit cell architecture, such as a standard cell for complementary metal oxide semiconductor (CMOS) circuits. In exemplary aspects an integrated circuit (IC) is provided that includes a diffusion region(s) formed in a substrate. Semiconductor devices, such as field-effect transistors (FETs) are formed in the diffusion region(s) in a back-end-of-line (BEOL) layer(s) in the IC. Metal contacts are formed in contact with gates, sources, and drains of FETs fabricated in the IC to provide connectivity to the FETs. Metal contact lines can be formed in contact with the metal contacts to provide routing of connections to the FETs. Vias are formed in contact with the metal contact lines to extend connectivity from the FETs to metal lines in upper metal interconnect layers including cell power rails. Thus, the resistance of cell power rails in the IC contributes to the overall resistance of the FETs formed therein. A high resistance causes a large current (I) resistance (R) (IR) drop, thereby reducing FET gate overdrive, which in turn reduces switching speed (i.e., increases delay). As node size is scaled down, the size of the power rails in an IC may also be reduced, thereby increasing resistance of the power rail and FETs coupled to the power rail in an undesired manner. Thus, in exemplary aspects disclosed herein, to reduce or mitigate an increase in resistance in the cell power rails in the IC, a complementary power rail(s) is formed in a MOL layer(s) of the IC and coupled to cell power rail(s) formed in a metal layer in a front-end-of-line (FEOL) layer in the IC. In examples disclosed herein, the MOL layer(s) in which the complementary power rail is formed is in a layer below the metal layer in the FEOL layer in which the cell power rail is formed. The complementary power rail has the effect of reducing the resistance of the cell power rail, and thus has the effect of reducing the resistance of FET(s) coupled to the cell power rail, thereby increasing performance. This is opposed to, for example, forming additional metal lines in higher metal layers above the metal layer of the cell power rail in the FEOL layer(s) of the IC, which can increase vertical height of the IC and thus increase circuit cell area in an undesired manner.

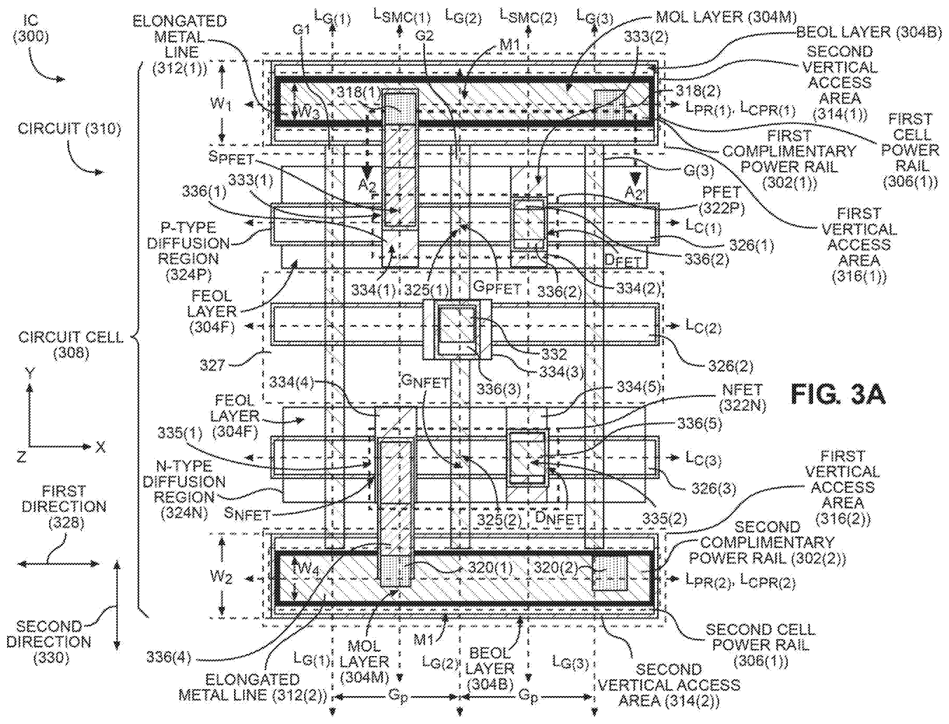

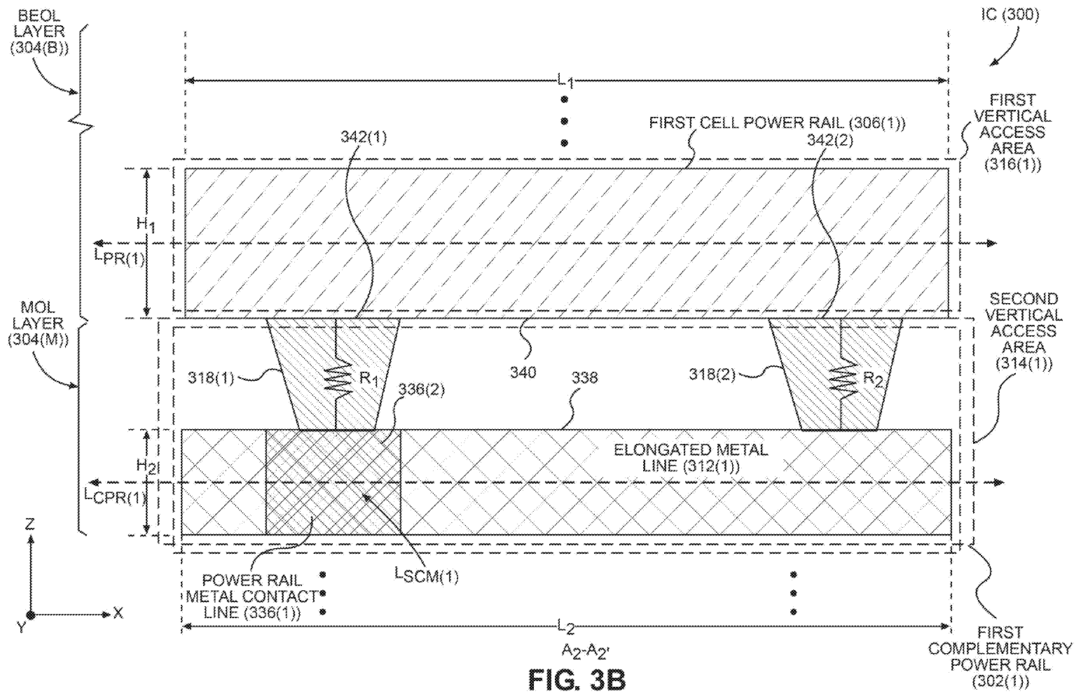

In this regard, FIGS. 3A and 3B illustrate an exemplary IC 300 that includes a first middle-of-line (MOL) complementary power rail 302(1) in a MOL layer 304M of the IC 300 coupled to a first cell power rail 306(1) in the IC 300 for reduced resistance. FIG. 3A is a top view of the IC 300 laid out according to an architecture of a circuit cell 308. The IC also includes an optional second MOL complementary power rail 302(2) in the MOL layer 304M coupled to a second power rail 306(2) in this example, but the IC 300 is not so limited. FIG. 3B is a cross-sectional side view taken in the A-A′ cross-sectional line of the IC 300 shown in FIG. 3A to further illustrate the first MOL complementary power rail 302(1) coupled to the first cell power rail 306(1) in the IC 300 for reduced resistance. The first and second cell power rails 306(1), 306(2) are conventional power rails that are formed in a metal interconnection layer (“metal layer”) in a BEOL layer 304B in the IC 300. The first and second cell power rails 306(1), 306(2) extend along longitudinal axes L_{PR(1)}, L_{PR(2)} in the X-axis direction as shown in FIG. 3A. For example, the first cell power rail 306(1) may be a positive supply voltage power rail that coupled to a positive supply voltage node configured to receive supply power. The second cell power rail 306(2) may be a voltage power rail that is coupled to a negative supply voltage node or ground node. In this example, the first and second cell power rails 306(1), 306(2) is formed in a metal one layer M1 in the BEOL layer 304B of the IC 300 immediately above the MOL layer 304M. The MOL layer 304M is fabricated above a FEOL layer 304F that is an active semiconductor layer where active devices, such as FETs, are formed to form a circuit 310 and may be coupled to the cell power rails 306(1), 306(2) for power.

As will be discussed in more detail below, in the example of the IC 300 in FIGS. 3A and 3B, the MOL complementary power rails 302(1), 302(2) are each in the form of respective first and second elongated metal lines 312(1), 312(2) fabricated in the MOL layer 304M in respective second vertical access areas 314(1), 314(2) in the MOL layer 304M in the IC 300 that overlap respective first vertical access areas 316(1), 316(2) occupied by the respective cell power rail 306(1), 306(2). In this example, the first and second complementary power rails 302(1), 302(2) extend along longitudinal axes L_{CPR(1)}, L_{CPR(2)} in the X-axis direction as shown in FIGS. 3A and 3B. The elongated metal lines 312(1), 312(2) of the complementary power rails 302(1), 302(2) are each coupled to its respective cell power rail 306(1), 306(2) through parallel connected vertical interconnect accesses (vias) 318(1), 318(2) and 320(1), 320(2). This is shown in FIG. 3B for the first cell power rail 306(1) and the first complementary power rail 302(1), where the vias 318(1), 318(2) of the first complementary power rail 302(1) couple the elongated metal line 312(1) of the first complementary power rail 302(1) to the cell power rail 306(1). Coupling the additional elongated metal lines 312(1), 312(2) to the respective cell power rails 306(1), 306(2) reduces the overall resistance of the cell power rails 306(1), 306(2). The parallel connected vias 318(1), 318(2) and 320(1), 320(2) also creates parallel via resistances R₁, R₂ in each of the first and second complementary power rails 302(1), 302(2), which reduces the overall via resistance of the first and second complementary power rails 302(1), 302(2), and thus the overall resistance of the respective cell power rails 306(1), 306(2). The first and second complementary power rails 302(1), 302(2) have the effect of reducing the resistance of the first and second cell power rails 306(2), 306(2), and thus have the effect of reducing the resistance of any FETs in the circuit 310 coupled to the first and/or second cell power rails 306(1), 306(2), thereby reducing their IR drop and increasing their performance.

Referring to FIG. 3A, the FEOL layer 304F in the IC 300 includes a PFET 322P in a first, P-type diffusion region 324P and an NFET 322N in a second, N-type diffusion region 324N formed in a substrate. A non-diffusion region 327 is between the P-type diffusion region 324P and the N-type diffusion region 324N. The PFET 322P and NFET 322N may be coupled together to form the circuit 310. The PFET 322P and NFET 322N are formed from semiconductor channels 325(1), 325(2) from the plurality of semiconductor channel structures 326(1)-326(3) in a respective P-type diffusion region 324P or N-type diffusion region 324N. For example, semiconductor channel structures 326(1)-326(3) may be fins of a semiconductor material if it is desired to form the PFET 322P and NFET 322N as FinFETs. However, the semiconductor channel structures 326(1)-326(3) could also be nano semiconductor structures (e.g., nanowires, nanoslabs) to form gate-all-around FETs or doped regions in the substrate to form planar FETs. The semiconductor channel structures 326(1)-326(3) each have respective longitudinal axes L_{C(1)}-L_{C(3)} in a first direction 328 of the X-axis in this example. The IC 300 also includes a plurality of gates G(1)-G(3) disposed above a substrate, wherein each of the gates G(1)-G(3) having longitudinal axes L_{G(1)}-L_{G(3)} in a second direction 330 of the Y-axis orthogonal to longitudinal axes L_{C(1)}-L_{C(3)} of the semiconductor channel structures 326(1)-326(3). In this example, gate G(2) is a conducting gate that can be used to form an active gate of the PFET 322P and NFET 322N. Gates G(1) and G(3) are dummy gates to form diffusion breaks between other adjacent circuits (not shown).

With continuing reference to FIG. 3A, the PFET 322P includes a source S_{PFET} and a drain D_{PFET} formed in end portions 333(1), 333(2) of the semiconductor channel 325(1), and an active gate G_{PFET} formed in the gate G(2) in the FEOL layer 304F. The NFET 322N includes a source S_{NFET} and a drain D_{NFET} formed in end portions 335(1), 335(2) of the semiconductor channel 325(2), and an active gate G_{NFET} also formed in the gate G(2) in the FEOL layer 304F. In this example, the gates G_{PFET}, G_{NFET} are formed in the same gate G(2) and tied together with a signal metal contact 334(3) in the circuit 310. A signal metal line 332 is disposed above and in contact with the signal metal contact 334(3) in the FEOL layer 304F to provide connectivity of the gates G_{PFET}, G_{NFET} in a metal layer in the MOL and BEOL layers 304M, 304B. Respective signal metal contacts 334(1)-334(2) and 334(4)-334(5) are disposed above and in contact with the respective source S_{PFET} and drain D_{PFET} of the PFET 322P, and the source S_{NFET} and the drain D_{NFET} of the NFET 322N. Power rail metal contact lines 336(1)-336(5) in the MOL layer 304M are disposed above and in contact with the respective signal metal contacts 334(1)-334(5) to provide interconnectivity through the MOL layer 304M to the metal interconnect lines in the BEOL layer 304B. The power rail metal contact lines 336(1), 336(4) are disposed along a longitudinal axis L_{SMC(1)} in the second direction 330 orthogonal to the longitudinal axes L_{PR(1)}, L_{PR(2)}, and power rail metal contact lines 336(2), 336(5) are disposed along the respective longitudinal axis L_{SMC(2)}. As shown in FIG. 3A, the power rail metal contact line 336(1) coupled to the signal metal contact 334(1) of the PFET 322P extends to the second vertical access area 314(1) below the first vertical access area 316(1) of the first cell power rail 306(1) to couple the source S_{PFET} of the PFET 322P to the first cell power rail 306(1). The power rail metal contact line 336(4) coupled to the signal metal contact 334(4) of the NFET 322N extends to the second vertical access area 314(2) below the first vertical access area 316(2) of the second cell power rail 306(2) to couple the source S_{NFET} of the NFET 322P to the second cell power rail 306(2).

With reference to FIG. 3B, the first complementary power rail 302(1) includes the elongated metal line 312(1) formed in the MOL layer 304M below the BEOL layer 304B. The elongated metal line 312(1) is in contact with the power rail metal contact line 336(1), which extends in the Y-axis direction in and out of the page of the view in FIG. 3B. To couple the first complementary power rail 302(1) to the first cell power rail 306(1), the vias 318(1), 318(2) are formed in contact with a top surface 338 of the first elongated metal line 312(1) and extend upward. The vias 318(1), 318(2) “stitch” the first elongated metal line 312(1) to the first cell power rail 306(1). For example, the first elongated metal line 312(1) may be of a low resistivity material, such as Copper, to reduce resistance. The first cell power rail 306(1) is formed in the BEOL layer 306B with its bottom surface 340 in contact with top surfaces 342(1), 342(2) of the respective vias 318(1), 318(2). As shown in FIG. 3B, the first cell power rail 306(1) has a length L₁ along its longitudinal axes L_{PR(1)} in in the X-axis direction. The first complementary power rail 302(1) has a length L₂ along its longitudinal axes L_{CPR(1)} in in the X-axis direction.

With continuing reference to FIG. 3B, in this example, the lengths L₁, L₂ of the first cell power rail 306(1) and the first complementary power rail 302(1) are equal or substantially equal, but such is not required. In this example, this is desired, because there is available space to provide this length L₂ of first complementary power rail 302(1) in the second vertical access area 314(1) in the IC 300 below the first vertical access area 316(1) occupied by the first cell power rail 306(1). The second via 318(2) for coupling of the elongated metal line 312(1) of the complementary power rail 302(1) to the cell power rail 306(1) is to also decrease via resistance. As previously discussed, the second via 318(2) has a resistance R₂ that forms a parallel resistance with the resistance R₁ of the first via 318(1) to decrease overall via resistance, and thus the overall resistance of the first cell power rail 306(1). As a non-limiting example, the ratio of the length L₂ of the first complementary power rail 302(1) to the length L₁ of the cell power rail 306(1) may be at least thirty percent (30%). Note that the features discussed above between the first cell power rail 306(1) and the first complementary power rail 302(1) can also be present between the second cell power rail 306(2) and the second complementary power rail 302(2). Further, as shown in FIG. 3A, the first and second cell power rails 306(1), 306(2) have widths W₁ and W₂ in the second direction 330 of the Y-axis, and the first and second complementary power rails 302(1), 302(2) have respective widths W₃ and W₄ in the second direction 330 of the Y-axis. The respective widths W₃, W₄ of the respective first and second complementary power rails 302(1), 302(2) may be equal or less than the respective widths W₁, W₂ of the first and second cell power rails 306(1), 306(2). For example, a ratio of the widths W₃ and W₄ of the first and second complementary power rails 302(1), 302(2) to the widths W₁, W₂ of the first and second cell power rails 306(1), 306(2) may be less than fifty percent (50%). Further, as shown in FIG. 3B, the first cell power rails 306(1) has a height H₁ in the direction of the Z-axis, and the first elongated metal line 312(1) has a height H₂ in the Z-axis direction.

If for example, the first elongated metal line 312(1) and the first cell power rail 306(1) are both made of Copper, and both have the same dimensions that includes respective 40 nm heights H₁, H₂ and respective 40 nm widths W₁, W₃, the complementary power rail 302(1) will lower the original resistance of just the first cell power rail 306(1) by approximately one-half (½), which would be equivalent to the first cell power rail 306(1) having a larger width W₁ of 65 nm instead of 40 nm to achieve a similar lower resistance. As another example, if the elongated metal line 312(1) and the first cell power rail 306(1) are both made of Cobalt and of the same dimensions, the resistance of the first cell power rail 306(1) will be approximately 81% of the original resistance of just the first cell power rail 306(1), which would be equivalent to the first cell power rail 306(1) having a larger width W₁ of 55 nm instead of 40 nm to achieve a similar lower resistance. As another example, if the first elongated metal line 312(1) is made of Cobalt and has a width W₂ to height H₂, ratio of 20 nm/40 nm for a width W₁ to height H₁ ratio of 40 nm/40 nm for the first cell power rail 306(1), the resistance of the first cell power rail 306(1) will be approximately 64% of the original resistance of just the first cell power rail 306(1), which would be equivalent to the first cell power rail 306(1) having a larger width W₁ of 47 nm instead of 40 nm to achieve a similar lower resistance.

The first and second elongated metal lines 312(1), 312(2) can be formed in a photolithography process as a non-limiting example. The elongated metal lines 312(1), 312(2) may be formed using the same mask and fabrication process step as used to form the power rail metal contact lines 336(1), 336(4) in which they are coupled, or may be formed using a separate mask and separate fabrication step process. In one example, this process of forming the first and second elongated metal lines 312(1), 312(2) of the complementary power rails 302(1), 302(2) involves forming a photoresist layer in the MOL layer 304M. A mask is disposed over the first photoresist layer. The mask is exposed to form an opening in an ILD in the second vertical access areas 314(1), 314(2) in the MOL layer 304M. Trenches can then be etched in the ILD below the openings and filled with a metal material to form the first and second elongated metal lines 312(1), 312(2) of the complementary power rails 302(1), 302(2). The power rail metal contact lines 336(1), 336(4) can formed in contact with the first and second elongated metal lines 312(1), 312(2) using a similar photolithography process an separately mask. Alternatively, the power rail metal contact lines 336(1), 336(4) can formed as part of the same mask and fabrication process as the first and second elongated metal lines 312(1), 312(2) described above. In this regard, the trench etched in the opening after exposing the mask would involve a trench that can be filled to form both the power rail metal contact lines 336(1), 336(4) and the elongated metal lines 312(1), 312(2), which is then filled with a metal material.

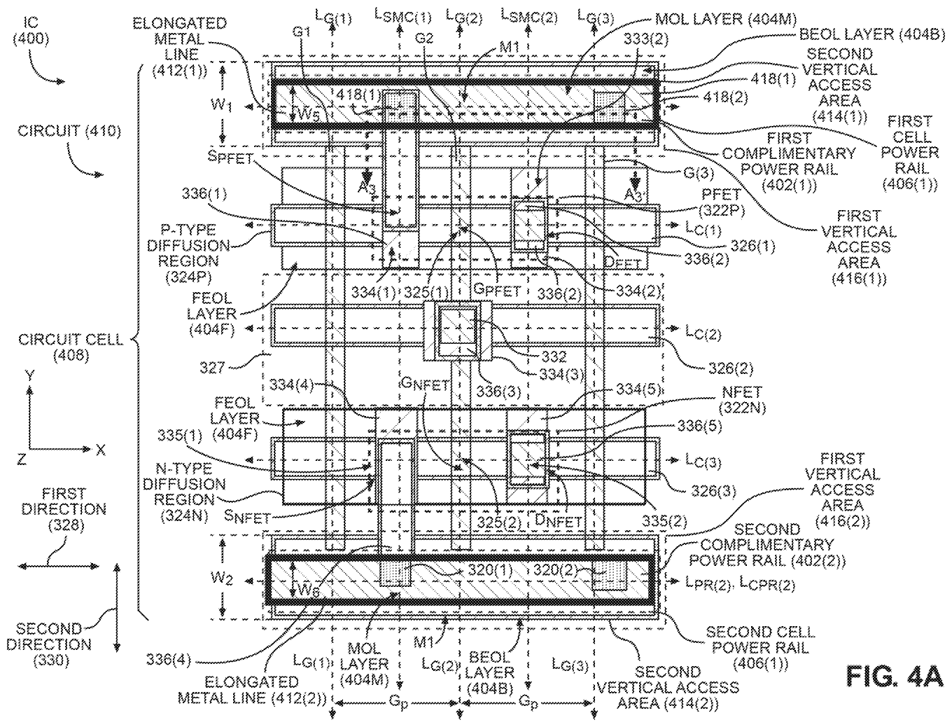

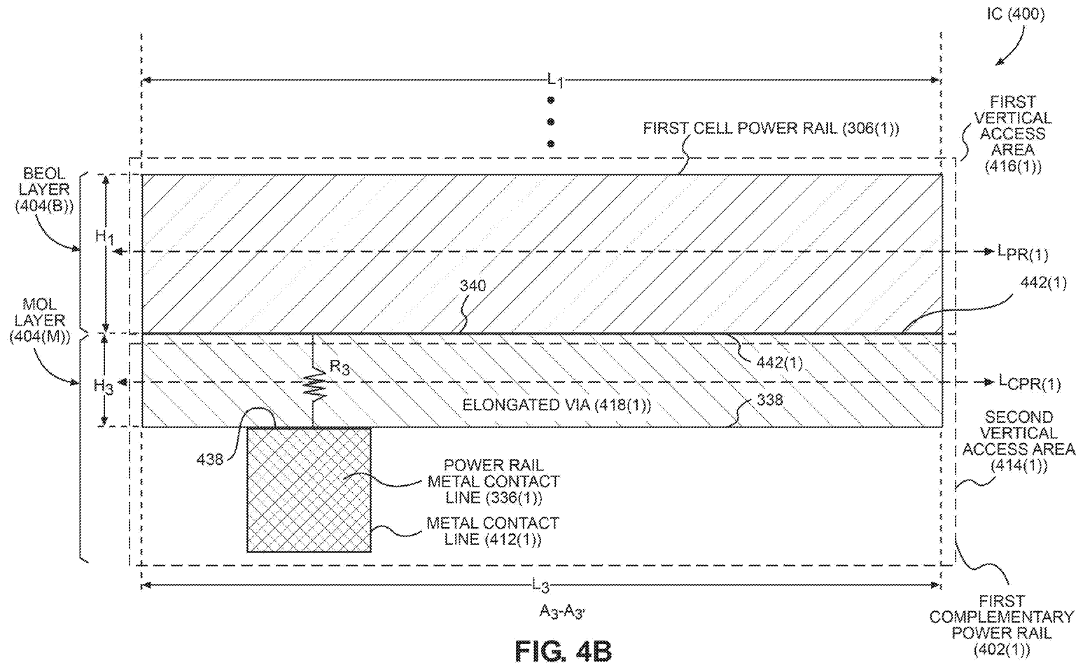

Other designs of providing a complementary power rail to be coupled to a cell power rail in an IC to lower the resistance of the cell power rail are possible and not limited to the example of the IC 300 in FIGS. 3A and 3B. For example, FIGS. 4A and 4B illustrate an exemplary IC 400 that is similar to the IC 300 in FIGS. 3A and 3B. The IC 400 in FIGS. 4A and 4B includes a first and second MOL complementary power rails 402(1), 402(2) in a MOL layer 404M of the IC 400 coupled to the respective first and second cell power rails 306(1), 306(2) in the BEOL layer 304B in the IC 400 for reduced resistance. As will be discussed in more detail below, the MOL complementary power rails 402(1), 402(2) in the IC 400 in this example include respective elongated vias 418(1), 418(2) fabricated below and in contact with the respective first and second cell power rails 306(1), 306(2) to reduce resistance of the first and second cell power rails 306(1), 306(2). The IC 400 in FIGS. 4A and 4B include the FEOL layer 304F and BEOL layer 304B in the IC 300 in FIGS. 3A and 3B and many common components between the MOL layer 404M and the MOL layer 304M in the IC 300. Common elements between the IC 300 in FIGS. 3A and 3B and the IC 400 in FIGS. 4A and 4B are shown with the same element numbers and labels between FIGS. 3A-4B, and thus will not be re-described below.

In this regard, FIG. 4A is a top view of the IC 400 laid out according to an architecture of a circuit cell 408. FIG. 4B is a cross-sectional side view taken in the A₃-A₃′ cross-sectional line of the IC 400 shown in FIG. 4A to further illustrate the first MOL complementary power rail 402(1) coupled to the first cell power rail 306(1) in the IC 400 for reduced resistance. As will be discussed in more detail below, in the example of the IC 400 in FIGS. 4A and 4B, the first and second complementary power rails 402(1), 402(2) are each in the form of respective first and second metal lines 412(1), 412(2) fabricated in the MOL layer 404M in the respective second vertical access areas 414(1), 414(2) in the MOL layer 404M in the IC 400 that overlap respective first vertical access areas 316(1), 316(2) occupied by the respective cell power rail 306(1), 306(2). In this example, the first and second complementary power rails 402(1), 402(2) extend along longitudinal axes L_{CPR(1)}, L_{CPR(2)} in the X-axis direction as shown in FIGS. 4A and 4B. The metal lines 412(1), 412(2) of the complementary power rails 402(1), 402(2) are each coupled to its respective cell power rail 306(1), 306(2) through the elongated vias 418(1), 418(2). This is shown in FIG. 4B for the first cell power rail 306(1) and the first complementary power rail 402(1), where the elongated via 418(1) having resistance R₃ of the first complementary power rail 402(1) is coupled to the first metal line 412(1) of the first complementary power rail 402(1) to the cell power rail 306(1). Coupling the additional metal lines 412(1), 412(2) to the respective cell power rails 306(1), 306(2) reduces the overall resistance of the cell power rails 306(1), 306(2). The elongated vias 418(1), 418(2) create a parallel via resistance R₃ in each of the first and second complementary power rails 402(1), 402(2), which reduces the overall via resistance of the first and second complementary power rails 402(1), 402(2), and thus the overall resistance of the respective cell power rails 306(1), 306(2). The first and second complementary power rails 402(1), 402(2) have the effect of reducing the resistance of the first and second cell power rails 306(2), 306(2), and thus has the effect of reducing the resistance of any FETs in the circuit 310 coupled to the first and/or second cell power rails 306(1), 306(2), thereby reducing their IR drop and increasing their performance.

With reference to FIG. 4B, the first complementary power rail 402(1) includes the first metal line 412(1) formed in the MOL layer 404M below the BEOL layer 304B. The first metal line 412(1) is in contact with the power rail metal contact line 336(2) in FIG. 4A. To couple the first complementary power rail 402(1) to the first cell power rail 306(1), the elongated via 418(1) is formed in contact with a top surface 438 of the first metal line 412(1). The elongated via 418(1) “stitches” the first metal line 412(1) to the first cell power rail 306(1). For example, the first metal line 412(1) and elongated via 418(1) may be of a low resistivity material, such as Copper, to reduce resistance. The first cell power rail 306(1) is formed in the BEOL layer 306M with its bottom surface 340 in contact with a top surface 442(1) of the elongated via 418(1). As shown in FIG. 4B, the first cell power rail 306(1) has the length L₁ along its longitudinal axes L_{PR(1)} in in the X-axis direction. The first complementary power rail 402(1) has a length L₃ along its longitudinal axes L_{CPR(1)} in in the X-axis direction.

With continuing reference to FIG. 4B, in this example, the lengths L₁, L₃ of the first cell power rail 306(1) and the first complementary power rail 402(1) are equal or substantially equal, but such is not required. In this example, this is desired, because there is available space to provide this length L₃ of the first complementary power rail 402(1) in the second vertical access area 414(1) in the IC 400 below the first vertical access area 416(1) occupied by the first cell power rail 306(1). As a non-limiting example, the ratio of the length L₃ of the first complementary power rail 402(1) to the length L₁ of the cell power rail 306(1) may be at least thirty percent (30%). Note that the features discussed above between the first cell power rail 306(1) and the first complementary power rail 402(1) can also be present between the second cell power rail 306(2) and the second complementary power rail 402(2). Further, as shown in FIG. 4A, the first and second cell power rails 306(1), 306(2) have widths W₁ and W₂ in the second direction 330 of the Y-axis, and the first and second complementary power rails 402(1), 402(2) have respective widths W₅ and W₆ in the second direction 330 of the Y-axis. The respective widths W₅, W₆ of the respective first and second complementary power rails 402(1), 402(2) may be equal or less than the respective widths W₁, W₂ of the first and second cell power rails 306(1), 306(2). For example, a ratio of the widths W₅ and W₆ of the first and second complementary power rails 402(1), 402(2) to the widths W₁, W₂ of the first and second cell power rails 306(1), 306(2) may be less than fifty percent (50%). Further, as shown in FIG. 4B, the first cell power rails 306(1) has a height H₁ in the direction of the Z-axis, and the first elongated via 418(1) has a height H₃ in the Z-axis direction. The fabrication process described for the MOL layer 304M in FIGS. 3A and 3B above can also be employed to fabricate the MOL layer 404M in the IC 400 in FIGS. 4A and 4B.

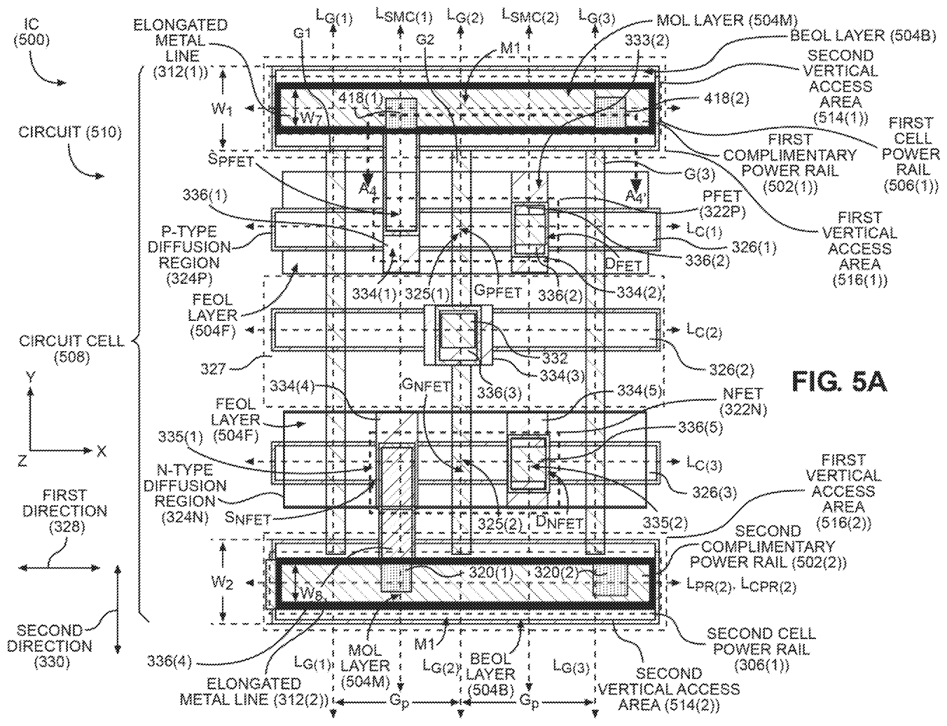

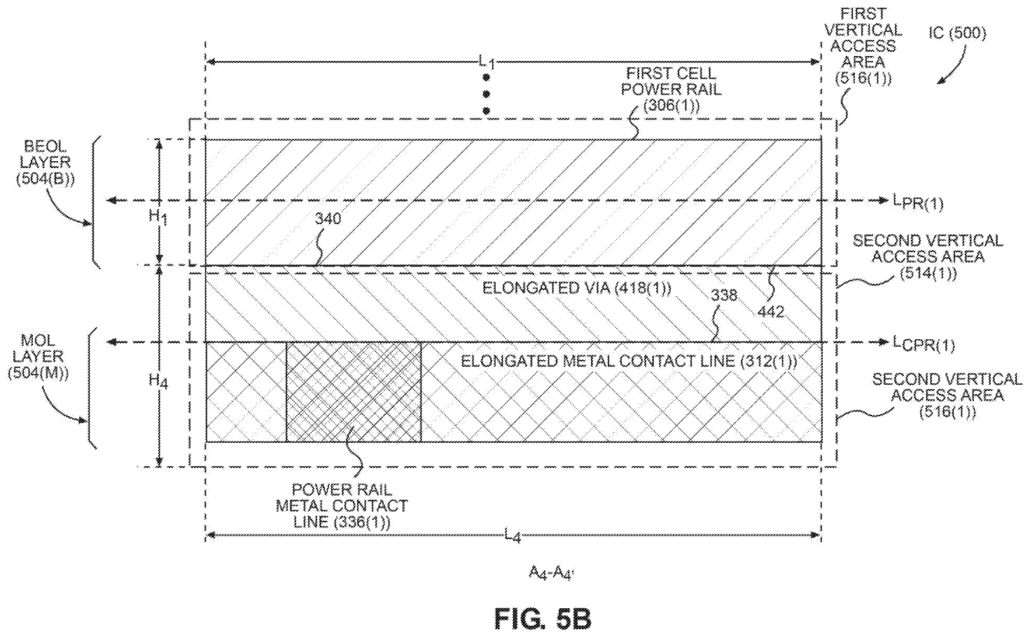

FIGS. 5A and 5B illustrate another exemplary IC 500 that is similar to the IC 300 in FIGS. 3A and 3B and IC 400 in FIGS. 4A and 4B. The IC 500 in FIGS. 5A and 5B includes first and second MOL complementary power rails 502(1), 502(2) in a MOL layer 504M of the IC 500 coupled to the respective first and second cell power rails 306(1), 306(2) in the BEOL layer 304B in the IC 500 for reduced resistance. As will be discussed in more detail below, the first and second complementary power rails 502(1), 502(2) in the IC 500 in this example include the respective elongated vias 418(1), 418(2) like in the IC 400 in FIGS. 4A and 4B fabricated below and in contact with the respective first and second cell power rails 306(1), 306(2) to reduce resistance of the first and second cell power rails 306(1), 306(2). The first and second complementary power rails 502(1), 502(2) also include respective elongated metal contact lines 312(1), 312(2) like in the IC 300 in FIGS. 3A and 3B formed in the MOL layer 504B below and in contact with the respective elongated vias 418(1), 418(2). The IC 500 in FIGS. 5A and 5B includes the FEOL layer 304F and BEOL layer 304B in the IC 300 in FIGS. 3A and 3B and many common components between the MOL layer 504M and the MOL layers 304M and 404M in ICs 300, 400 in FIGS. 3A-4B. Common elements between IC 500 in FIGS. 5A and 5B are shown with the same element numbers and labels between FIGS. 3A-4B, and thus will not be re-described below.

In this regard, FIG. 5A is a top view of the IC 500 laid out according to an architecture of a circuit cell 508. Figure SB is a cross-sectional side view taken in the A₄-A₄′ cross-sectional line of the IC 500 shown in FIG. 5A to further illustrate the first MOL complementary power rail 502(1) coupled to the first cell power rail 306(1) in the IC 500 for reduced resistance. As will be discussed in more detail below, in the example of the IC 500 in FIGS. 5A and 5B, the first and second complementary power rails 502(1), 502(2) are each in the form of respective first and second elongated metal lines 312(1), 312(2) fabricated in the MOL layer 504M in the respective second vertical access areas 514(1), 514(2) in the MOL layer 504M in the IC 500 that overlaps the respective first vertical access areas 516(1), 516(2) occupied by the respective cell power rails 506(1), 506(2). In this example, the first and second complementary power rails 502(1), 502(2) extend along longitudinal axes L_{CPR(1)}, L_{CPR(2)} in the X-axis direction as shown in FIGS. 5A and 5B. The elongated metal lines 312(1), 312(2) of the complementary power rails 502(1), 502(2) are each coupled to its respective cell power rail 306(1), 306(2) through the elongated vias 418(1), 418(2). This is shown in FIG. 5B for the first cell power rail 306(1) and the first complementary power rail 502(1), where the elongated via 418(1) having resistance R₃ of the first complementary power rail 502(1) is coupled to the elongated metal line 312(1) of the first complementary power rail 502(1) to the cell power rail 306(1). The elongated vias 418(1), 418(2) and elongated metal lines 312(1), 312(2) in each of the first and second complementary power rails 502(1), 502(2) reduce the overall via resistance of the first and second complementary power rails 502(1), 502(2), and thus the overall resistance of the respective cell power rails 306(1), 306(2). The first and second complementary power rails 502(1), 502(2) have the effect of reducing the resistance of the first and second cell power rails 306(2), 306(2), and thus have the effect of reducing the resistance of any FETs in the circuit 510 in the IC 500 coupled to the first and/or second cell power rails 306(1), 306(2), thereby reducing their IR drop and increasing their performance.

With reference to FIG. 5B, the first complementary power rail 502(1) includes the first elongated metal line 312(1) formed in the MOL layer 504M below the BEOL layer 304B. The elongated metal line 312(1) is in contact with the power rail metal contact line 336(2) in FIG. 5A. To couple the first complementary power rail 502(1) to the first cell power rail 306(1), the elongated via 418(1) is formed in contact with a top surface 438 of the first elongated metal line 312(1). The elongated via 418(1) “stitches” the first elongated metal line 312(1) to the first cell power rail 306(1). For example, the first elongated metal line 312(1) and elongated via 418(1) may be of a low resistivity material, such as Copper, to reduce resistance. The first cell power rail 306(1) is formed in the BEOL layer 306M with its bottom surface 340 in contact with a top surface 442(1) of the elongated via 418(1). As shown in FIG. 5B, the first cell power rail 306(1) has the length L₁ along its longitudinal axes L_{PR(1)} in in the X-axis direction. The first complementary power rail 502(1) has a length L₄ along its longitudinal axes L_{CPR(1)} in in the X-axis direction.

With continuing reference to FIG. 5B, in this example, the lengths L₁, L₄ of the first cell power rail 306(1) and the first complementary power rail 502(1) are equal or substantially equal, but such is not required. In this example, this is desired, because there is available space to provide this length L₄ of first complementary power rail 502(1) in the second vertical access area 514(1) in the IC 400 below the first vertical access area 316(1) occupied by the first cell power rail 306(1). As a non-limiting example, the ratio of the length L₄ of the first complementary power rail 502(1) to the length L₁ of the cell power rail 306(1) may be at least thirty percent (30%). Note that the features discussed above between the first cell power rail 306(1) and the first complementary power rail 502(1) can also be present between the second cell power rail 306(1) and the second complementary power rail 502(2). Further, as shown in FIG. 5A, the first and second cell power rails 306(1), 306(2) have widths W₁ and W₂ in the second direction 330 of the Y-axis, and the first and second complementary power rails 502(1), 502(2) have respective widths W₇ and W_{R} in the second direction 330 of the Y-axis. The respective widths W₇, W₈ of the respective first and second complementary power rails 502(1), 502(2) may be equal or less than the respective widths W₁, W₂ of the first and second cell power rails 306(1), 306(2). For example, a ratio of the widths W₇ and W₈ of the first and second complementary power rails 302(1), 302(2) to the widths W₁, W₂ of the first and second cell power rails 306(1), 306(2) may be less than fifty percent (50%). Further, as shown in FIG. 5B, the first cell power rail 306(1) has a height H₁ in the direction of the Z-axis, and the first complementary power rail 502(1) has a height H₄ in the Z-axis direction. The fabrication process described for the MOL layer 304M in FIGS. 3A and 3B above can also be employed to fabricate the MOL layer 504M in the IC 500 in FIGS. 5A and 5B.

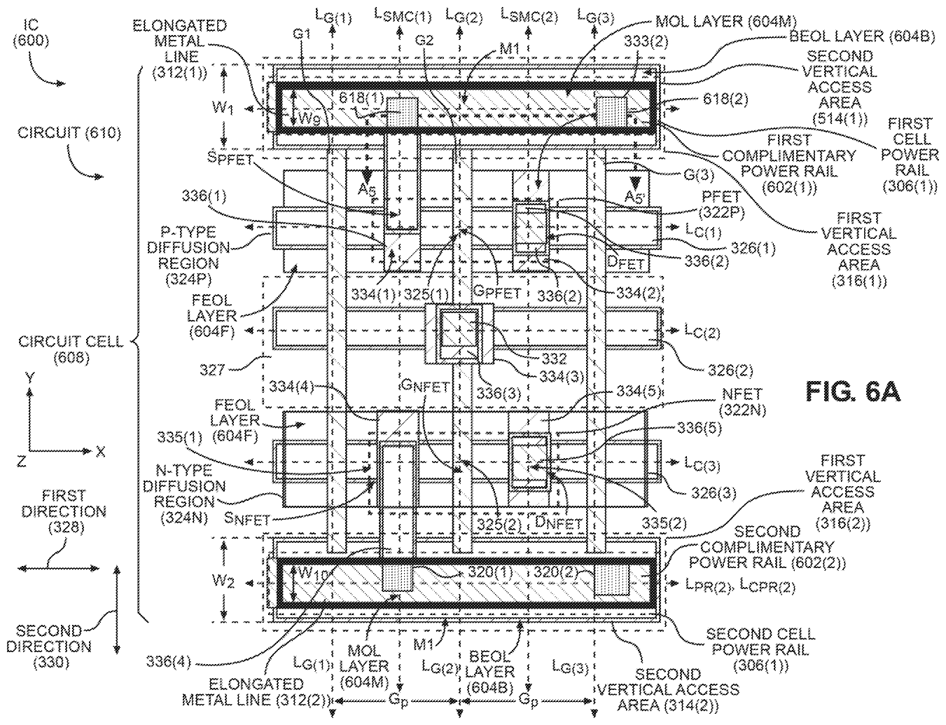

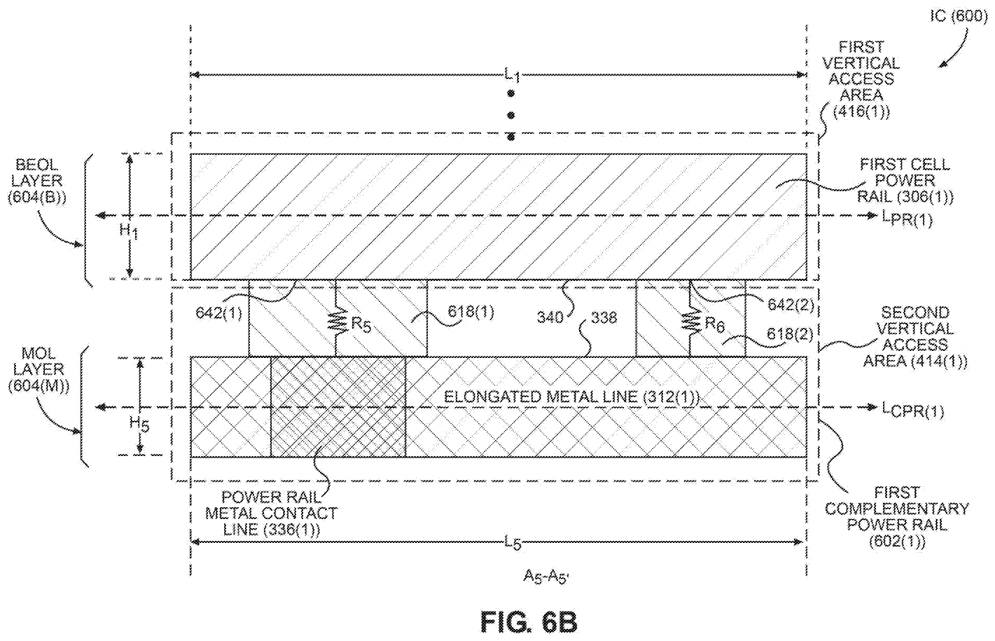

FIGS. 6A and 6B illustrate another exemplary IC 600 that is similar to the IC 300 in FIGS. 3A and 3B. The IC 600 in FIGS. 4A and 4B includes a first and second MOL complementary power rails 602(1), 602(2) in a MOL layer 604M of the IC 600 coupled to the respective first and second cell power rails 306(1), 306(2) in the BEOL layer 304B in the IC 600 for reduced resistance. As will be discussed in more detail below, the first and second complementary power rails 602(1), 602(2) in the IC 600 in this example include respective elongated metal lines 312(1), 312(2) like in the IC 300 in FIGS. 3A and 3B. Vias 618(1), 618(2) are formed on a top surface 338 of the elongated metal lines 312(1), 312(1) to couple the elongated metal lines 312(1), 312(2) to the respective first and second cell power rails 306(1), 306(2) to reduce resistance of the first and second cell power rails 306(1), 306(2). The IC 600 in FIGS. 6A and 6B includes the FEOL layer 304F and BEOL layer 304B present in the IC 300 in FIGS. 3A and 3B and many common components between the MOL layer 604M and the MOL layer 304M in the IC 300, 400 in FIGS. 3A and 3B. Common elements between IC 600 in FIGS. 5A and 5B are shown with the same element numbers and labels between FIGS. 3A and 3B, and thus will not be re-described below.

In this regard, FIG. 6A is a top view of the IC 600 laid out according to an architecture of a circuit cell 608. FIG. 6B is a cross-sectional side view taken in the A₅-A₅′ cross-sectional line of the IC 600 shown in FIG. 6A to further illustrate the first MOL complementary power rail 602(1) coupled to the first cell power rail 306(1) in the IC 600 for reduced resistance. As shown in FIG. 6B, the first complementary power rail 602(1) includes the first elongated metal line 312(1) formed in the MOL layer 604M below the BEOL layer 304B. The first elongated metal line 312(1) is in contact with the power rail metal contact line 336(2) shown in FIG. 6A. To couple the first complementary power rail 602(1) to the first cell power rail 306(1), the vias 618(1), 618(2) are formed in contact with a top surface 338 of the first elongated metal line 312(1) and extend upward. The vias 618(1), 618(2) “stitch” the first elongated metal line 312(1) to the first cell power rail 306(1). For example, the first elongated metal line 312(1) may be of a low resistivity material, such as Copper, to reduce resistance. The first cell power rail 306(1) is formed in the BEOL layer 306M with its bottom surface 340 in contact with top surfaces 642(1), 642(2) of the respective vias 618(1), 618(2). As shown in FIG. 6B, the first cell power rail 306(1) has a length L₁ along its longitudinal axes L_{PR(1)} in in the X-axis direction. The first complementary power rail 602(1) has a length L₅ along its longitudinal axes L_{CPR(1)} in in the X-axis direction.

With continuing reference to FIG. 6B, in this example, the lengths L₁, L₅ of the first cell power rail 306(1) and the first complementary power rail 602(1) are equal or substantially equal, but such is not required. In this example, this is desired, because there is available space to provide this length L₅ of first complementary power rail 602(1) in the second vertical access area 314(1) in the IC 300 below the first vertical access area 316(1) occupied by the first cell power rail 306(1). The second via 618(2) for coupling the first elongated metal line 312(1) of the complementary power rail 302(1) to the cell power rail 306(1) is to also decrease via resistance. The second via 618(2) is elongated to further reduce its resistance connected in parallel to the first via 618(1), and to reduce the overall via resistance of the first complementary power rail 602(1). The second elongated via 618(2) has a resistance R₆ that forms a parallel resistance with the resistance R₅ of the first via 618(1) to decrease overall via resistance, and thus the overall resistance of the first cell power rail 606(1). As a non-limiting example, the ratio of the length L₅ of the first complementary power rail 602(1) to the length L₁ of the cell power rail 306(1) may be at least thirty percent (30%). Note that the features discussed above between the first cell power rail 306(1) and the first complementary power rail 602(1) can also be present between the second cell power rail 306(2) and the second complementary power rail 602(2). Further, as shown in FIG. 6A, the first and second cell power rails 306(1), 306(2) have widths W₁ and W₂ in the second direction 330 of the Y-axis, and the first and second complementary power rails 602(1), 602(2) have respective widths W₉ and W₁₀ in the second direction 330 of the Y-axis. The respective widths W₉, W₁₀ of the respective first and second complementary power rails 602(1), 602(2) may be equal or less than the respective widths W₁, W₂ of the first and second cell power rails 306(1), 306(2). For example, a ratio of the widths W₉ and W₁₀ of the first and second complementary power rails 602(1), 602(2) to the widths W₁, W₂ of the first and second cell power rails 306(1), 306(2) may be less than fifty percent (50%). Further, as shown in FIG. 3B, the first cell power rail 306(1) has a height H₁ in the direction of the Z-axis, and the first complementary power rail 602(1) has a height H₅ in the Z-axis direction. The fabrication process described for the MOL layer 304M in FIGS. 3A and 3B above can also be employed to fabricate the MOL layer 604M in the IC 600 in FIGS. 6A and 6B.

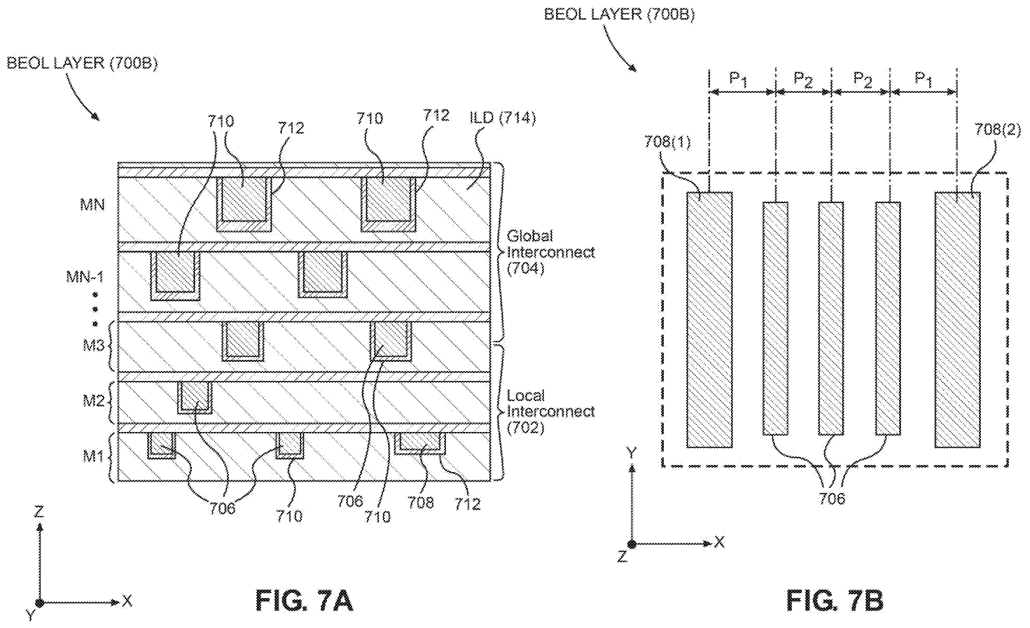

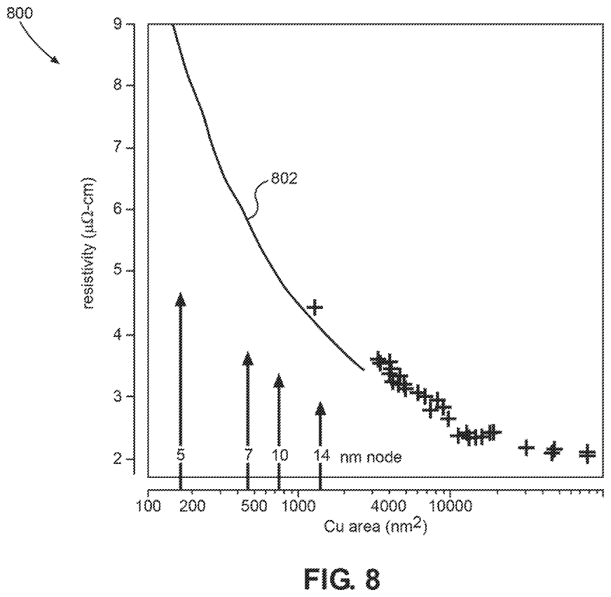

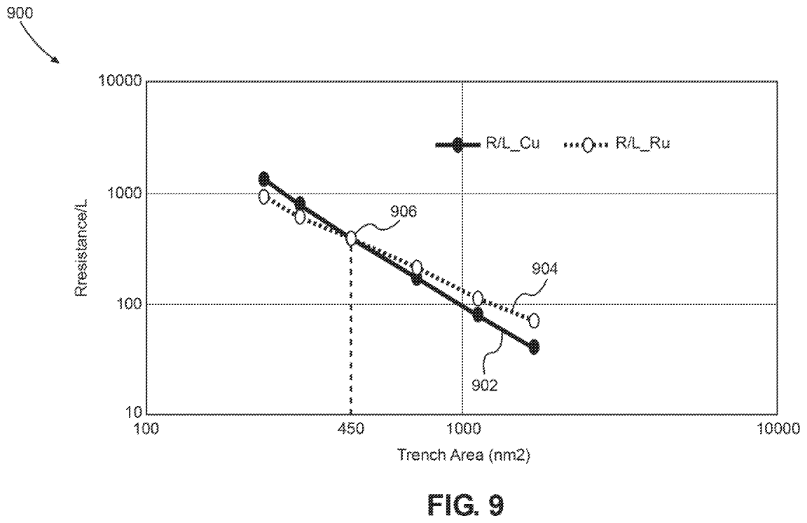

The metal interconnect layers, such as in the BEOL layer, in the ICs 300, 400, 500, 600 in FIGS. 3A-6B can be fabricated using metal material that also contributes to the overall resistance of the cell power rails. For example, FIGS. 7A and 7B are side and top views, respectively, of an exemplary BEOL layer 700B that can be fabricated in an IC to provide local interconnect metal layers 702 and global interconnect metal layers 704 for forming metal interconnect lines. For example, these metal interconnect lines can include signal lines 706 and power rails 708 as shown. The signal lines 706 and power rails 708 are formed by disposing metal, such as Copper, in trenches formed in an ILD 714 that are lined with barrier layers 710, 712 to prevent or reduce diffusion of the metal in the ILD 714. Copper has a low resistivity. For example, FIG. 8 is a graph 800 illustrating the resistivity of Copper in the Y-axis as a function of metal area in the X-axis and node size of an IC. As shown therein, as the node size reduces (e.g., from 14 nm, to 10 nm, to 7 nm, to 5 nm), the resistivity of Copper exponentially increases. This is because between the power rails 708 and signal lines 706 as shown in FIG. 7B, there is less area available for metal material to form the signal lines 706 and the power rails 708. If the barrier layers 710, 712 are reduced in thickness to allow additional metal material to be used to form the signal lines 706 and the power rails 708, it is more likely diffusion will occur between the Copper metal and the ILD 714. This is shown in the graph 900 in FIG. 9 that shows resistance per unit L (R/L) in the Y-axis as a function of the trench area for forming metal lines. Curve 902 shows the R/L for a given trench area for Copper. However, it is noticed that curve 904, which shows the R/L for a given trench area for Ruthenium (Ru), is less than Copper once the trench area goes below a crossover point 906.

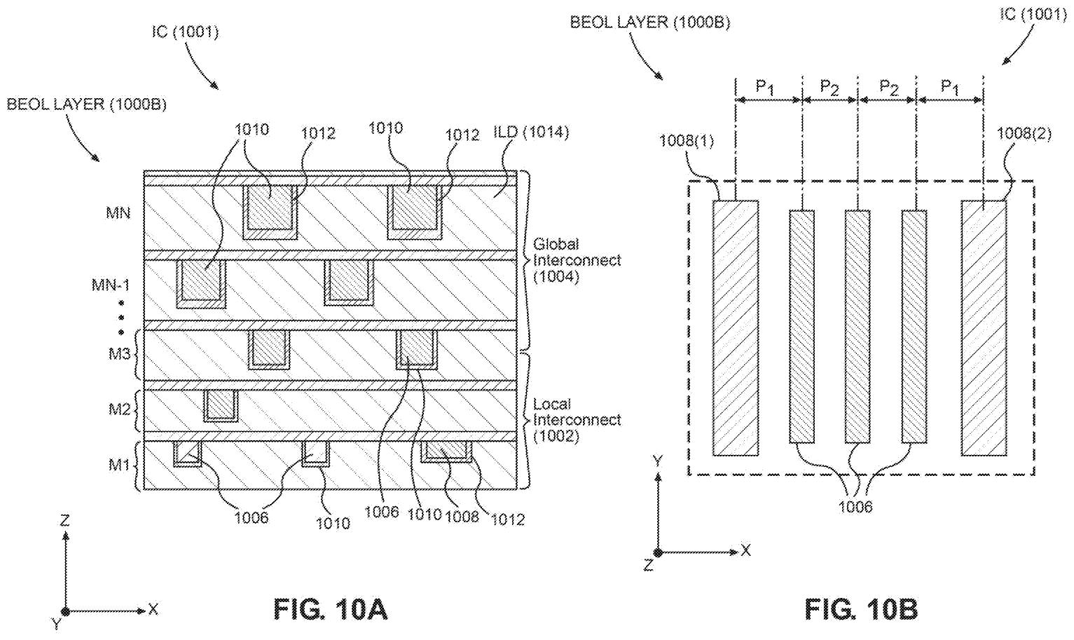

Thus, as shown, for example, in side and top view in FIGS. 10A and 10B, a BEOL layer 1000B is shown and can be used in the fabrication of an IC to further reduce resistance or mitigate an increase in resistance in an IC in either local interconnect layers 1002 or global interconnect layers 1004, such as a result of scaling down the size of cell circuits in the IC. In this regard, signal lines 1006 can be formed from a metal, such as Ruthenium (Ru) or Cobalt (Co), that can employ a thinner barrier layer 1010 to reduce or prevent metal diffusion into ILD 1014. For example, Copper has a low resistivity, but requires a thicker barrier layer to prevent diffusion. Thus, use of Copper may be advantageous for power rails 1008 for lower resistance, because power rails 1008 are larger in area. Thus, the barrier layer 1012 may not be required to be reduced in thickness as much as the barrier layer 1010 for signal lines 1006, due to scaling down of an IC employing the BEOL layer 1000B. Thus, to avoid having to trade off either use of a lower resistivity material, such as Copper, at the expense of a thicker barrier layer (e.g., 35 Angstroms (A)) which may increase signal line 1006 resistance, or using a higher resistivity material for the power rails 1008 that is less susceptive to diffusion and thus may allow use of a thinner barrier layer (e.g., 10-15 A), a lower resistivity material, such as Copper, is used for the power rails 1008, whereas a higher resistivity material, such as Ruthenium (Ru) or Cobalt (Co), is used for signal lines 1006. The reduced barrier layer 1010 thickness for the signal lines 1006 allowing a larger volume of a higher resistivity metal may result in a signal line 1006 with a lower resistance than a smaller volume of a lower resistivity metal due to a thicker barrier layer (e.g., 35 A).

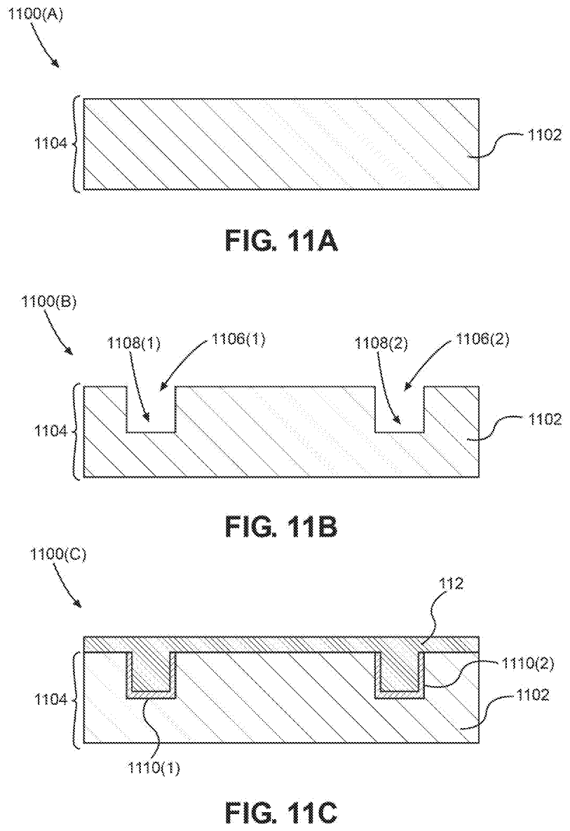

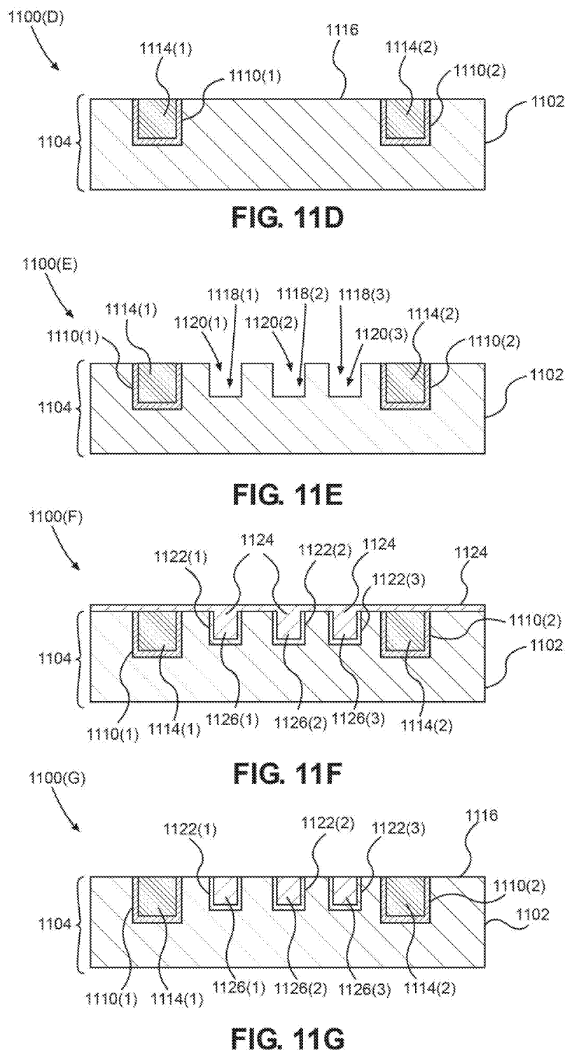

FIGS. 11A-11G are side views of exemplary fabrication stages 1100(A)-1100(G) of fabricating cell power rails of higher resistivity material encompassed by a thicker barrier layer, and signal metal lines with a lower resistivity encompassed by a thinner barrier layer in local interconnect layers in MOL layers in an IC. In this regard, as illustrated in fabrication stage 1100(A) in FIG. 11A, the process involves providing an ILD 1102 in a MOL layer 1104. Then, as illustrated in the fabrication stage 1100(B) in FIG. 11B, a lithography process is used to mask and expose openings 1106(1), 1106(2) in the ILD 1102 to then etch trenches 1108(1), 1108(2) below the openings 1106(1), 1106(2). Then, as illustrated in the fabrication stage 1100(C) in FIG. 11C, barrier layers 1110(1), 1110(2) are formed in the respective trenches 1108(1), 1108(2). The trenches 1108(1), 1108(2) are then filled with a metal material 1112 on top of the first barrier layers 1110(1), 1110(2) formed in the trenches 1108(1), 1108(1). For example, the metal material may be Copper (Cu) that has a low resistivity. A chemical mechanical planarization (CMP) process can be employed, as shown in fabrication stage 1100(D) in FIG. 11D, to planarize the metal material 1112 to form individual signal metal lines in the form of power rails 1114(1), 1114(1) down to a top surface 1116 of the ILD 1102.

As shown in the fabrication stage 1100(E) in FIG. 11E, a separate lithography process is then employed to form openings 1118(1)-1118(3) in the ILD 1102 and etch trenches 1120(1)-1120(3) below the respective openings 1118(1)-1118(3) to form signal metal lines. As illustrated in the fabrication stage 1100(F) in FIG. 11F, second barrier layers 1122(1)-1122(3) are formed in the respective trenches 1120(1)-1120(3). The trenches 1120(1)-1120(3) are then filled with a higher resistivity metal material 1124 on top of the second barrier layers 1122(1)-1122(3) formed in the trenches 1120(1)-1120(3) to form respective signal metal lines 1126(1)-1126(3) as shown in the fabrication stage 1100(F) in FIG. 11F. For example, the higher resistivity metal material 1124 may be Ruthenium (Ru) or Cobalt (Co) that has a higher resistivity than the Copper (Cu) used to form the power rails 1114(1), 1114(2). A chemical mechanical planarization (CMP) process can be employed, as shown in fabrication stage 1100(G) in FIG. 11G, to planarize the higher resistivity metal material 1124 to form individual signal metal lines 1126(1)-1126(3) down to the top surface 1116 of the ILD 1102. The second barrier layers 1122(1)-1122(3) for the signal metal lines 1126(1)-1126(3) may have a reduced thickness over the barrier layers 1110(1)-1110(3) for the power rails 1114(1), 1114(2), allowing a larger volume of a higher resistivity metal material 1124 to be used for the signal metal lines 1126(1)-1126(3) to mitigate the thinner, second barrier layers 1122(1)-1122(3) to support reduced scaling. The higher resistivity metal material 1124 is less susceptible to diffusion through the thinner, second barrier layers 1122(1)-1122(3). The power rails 1114(1), 1114(2) are formed with thicker barrier layers 1110(1), 1110(2) and a lower resistivity metal material since scaling may not require the power rails 1114(1), 1114(2) to be scaled as small as the signal metal lines 1126(1)-1126(3).

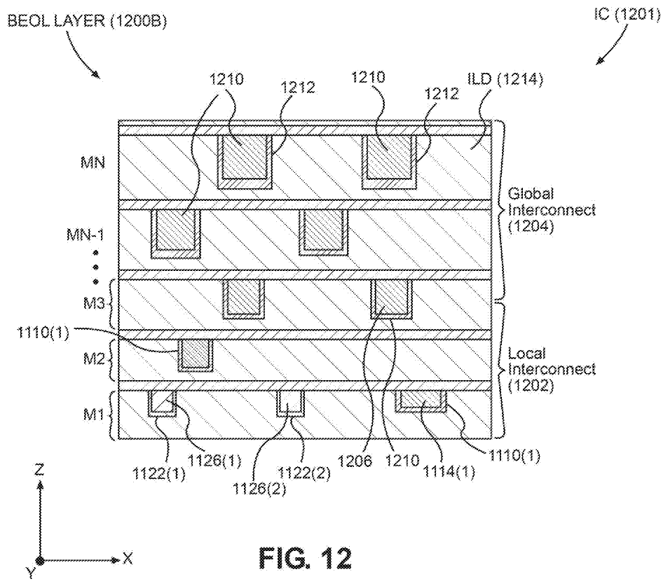

FIG. 12 is a side view a BEOL layer 1200B that may fabricated as a result of the exemplary process illustrated in the exemplary fabrication stages 1100(A)-1100(G) in FIGS. 11A-11G. The M1 layer illustrates signal metal lines 1126(1), 1126(2) of a higher resistivity material, such as Ruthenium (Ru) or Cobalt (Co), and a power rail 1114(1) of a lower resistivity material, such as Copper (Cu), that can be formed from a metal, such as Ruthenium (Ru) or Cobalt (Co), that can employ a thinner barrier layer 1110(1) to reduce or prevent metal diffusion into ILD 1014 as previously described above. This is avoid having to trade off either using a lower resistivity material, such as Copper (Cu), at the expense of a thicker barrier layer 1110(1) (e.g., 35 A) which may limit the metal material and thus increase signal metal line 1126(1), 1126(2) resistance, or using a higher resistivity material, such as Ruthenium (Ru) or Cobalt (Co), for the power rail 1114(1) that is less susceptive to diffusion and thus may allow use of a thinner barrier layer 1110(1) (e.g., 10-15 A), but has a higher resistance. The reduced second barrier layer 1122(1), 1122(2) thickness for the signal metal lines 1126(1), 1126(2) allowing a larger volume of a higher resistivity metal may result in a lower signal metal line 1126(1), 1126(2) resistance than a smaller volume of a lower resistivity metal with a thicker barrier layer 1110(1) (e.g., 35 A).

The IC comprises the FEOL layer. The FEOL layer comprises a means for providing a diffusion in a substrate. Examples of a means for providing a diffusion include, but are not limited to, the P-type and N-type diffusion regions 324P, 324N in the ICs 300, 400, 500, 600 in FIGS. 3A-6B. The FEOL layer also comprises a means for providing a semiconducting conduction path in the means for providing the diffusion. Examples of a means for providing a semiconducting conduction path in the means for providing a diffusion include, but are not limited to, the semiconductor structures 326(1)-326(3) in the ICs 300, 400, 500, 600 in FIGS. 3A-6B. The FEOL layer also comprises a plurality of means for controlling the means for providing the semiconducting conduction path disposed above the substrate. Examples of a plurality of means for controlling the means for providing the semiconducting conduction path include, but are not limited to gates G(1)-G(3) in the ICs 300, 400, 500, 600 in FIGS. 3A-6B. The FEOL layer also comprises a FET. The FET comprises a semiconductor channel in in the means for providing a semiconducting conduction path, an active gate in a portion of the means for controlling the means for providing the semiconducting conduction path adjacent to the semiconductor channel, a source in a first end portion of the semiconductor channel, and a drain in a second end portion of the semiconductor channel. The FEOL layer also comprises a means for providing a signal contact disposed above and in contact with one of the first active gate, the source, and the drain. The IC also comprises a BEOL layer disposed above the FEOL layer. Examples of a means for providing a signal contact disposed above and in contact with one of the first active gate, the source, and the drain include, but are not limited to, power rail metal contact lines 336(1)-336(5) in the ICs 300, 400, 500, 600 in FIGS. 3A-6B. The BEOL layer comprises a metal interconnect layer comprising a means for providing a cell power node disposed in a first vertical access area and coupled to a supply voltage node configured to receive a supply voltage. Examples of a means for providing a cell power node disposed in a first vertical access area and coupled to a supply voltage node configured to receive a supply voltage include, but are not limited to, first and second cell power rails 306(1), 306(2) in the ICs 300, 400, 500, 600, 1008, and 1114(1) in FIGS. 3A-6B, 10, and 12. The IC also comprises a MOL layer disposed between the FEOL layer and the BEOL layer. The MOL layer comprises a means for providing a signal contact coupling in contact with the means for providing a signal contact, and a complementary means for providing a cell power node disposed in a second vertical access area. Examples of a means for providing a signal contact coupling in contact with the means for providing a signal contact include, but are not limited to, the metal lines 312(1), 312(2), 412(1), 412(2) in the ICs 300, 400, 500, and 600 in FIGS. 3A-6B. The MOL layer also comprises the complementary means for providing a cell power node coupled to the means for providing a signal contact coupling and the means for providing a cell power node. Examples of a complementary means for providing a cell power node disposed in a second vertical access area include, but are not limited to, complementary power rails 302(1), 302(2), 402(1), 402(2), 502(1), 502(2), and 602(1), 602(2) in the ICs 300, 400, 500, and 600 in FIGS. 3A-6B. The complementary means for providing a cell power node is coupled to the means for providing a signal contact coupling and the means for providing a cell power node.

ICs includes a MOL complementary power rail(s) coupled to a cell power rail(s) in the IC for reduced resistance, including but not limited to the ICs 300, 400, 500, 600, 1001, and 1201 in FIGS. 3A-6B, 10, and 12, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

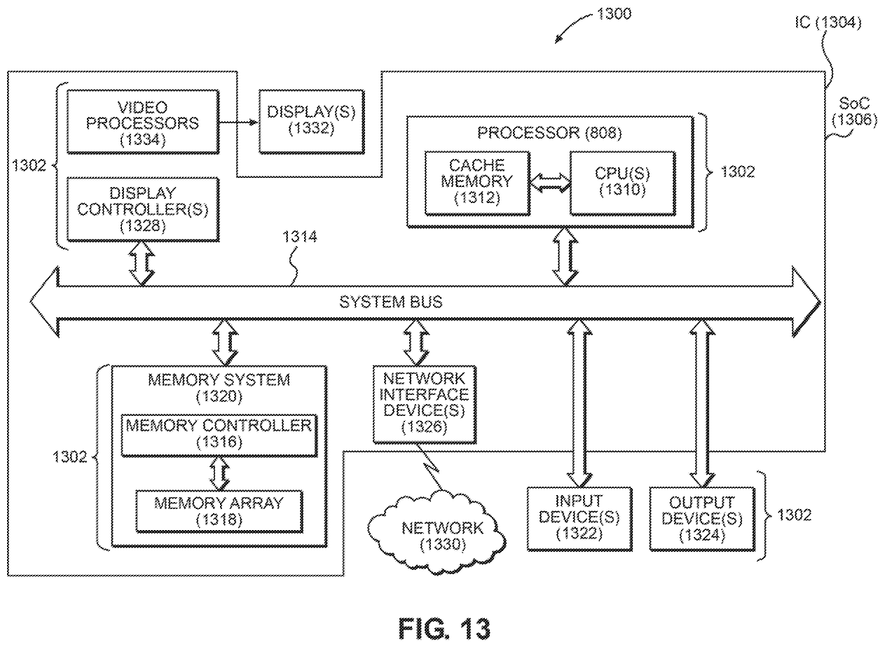

In this regard, FIG. 13 illustrates an example of a processor-based system 1300 that can include an IC(s) 1304 that includes a MOL complementary power rail(s) coupled to a cell power rail(s) in the IC for reduced resistance, including but not limited to the ICs 300, 400, 500, 600, 1001, and 1201 in FIGS. 3A-6B, 10 and 12, and according to any aspects disclosed herein. In this example, the processor-based system 1300 may be formed as an IC 1304 in a system-on-a-chip (SoC) 1306. The processor-based system 1300 includes a processor 1308 that includes one or more central processor units (CPUs) 1310, which may also be referred to as CPU or processor cores. The processor 1308 may have cache memory 1312 coupled to the processor(s) 1308 for rapid access to temporarily stored data. As an example, the cache memory 1312 could include an IC(s) 1304 that includes a MOL complementary power rail(s) coupled to a cell power rail(s) in the IC for reduced resistance, including but not limited to the ICs 300, 400, 500, 600, 1001, and 1201 in FIGS. 3A-6B, 10, and 12, and according to any aspects disclosed herein. The processor 1308 is coupled to a system bus 1314 and can intercouple master and slave devices included in the processor-based system 1300. As is well known, the processor 1308 communicates with these other devices by exchanging address, control, and data information over the system bus 1314. For example, the processor 1308 can communicate bus transaction requests to a memory controller 1316 as an example of a slave device. Although not illustrated in FIG. 13, multiple system buses 1314 could be provided, wherein each system bus 1314 constitutes a different fabric.

Other master and slave devices can be connected to the system bus 1314. As illustrated in FIG. 13, these devices can include a memory system 1320 that includes the memory controller 1316 and a memory array(s) 1318, one or more input devices 1322, one or more output devices 1324, one or more network interface devices 1326, and one or more display controllers 1328, as examples. Each of the memory systems 1320, the one or more input devices 1322, the one or more output devices 1324, the one or more network interface devices 1326, and the one or more display controllers 1328 can include an IC(s) 1304 that includes a MOL complementary power rail(s) coupled to a cell power rail(s) in the IC for reduced resistance, including but not limited to the ICs 300, 400, 500, 600, 1101, and 1201 in FIGS. 3A-6B 10, and 12, and according to any aspects disclosed herein. The input device(s) 1322 can include any type of input device, including, but not limited to, input keys, switches, voice processors, etc. The output device(s) 1324 can include any type of output device, including, but not limited to, audio, video, other visual indicators, etc. The network interface device(s) 1326 can be any device configured to allow exchange of data to and from a network 1330. The network 1330 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1326 can be configured to support any type of communications protocol desired.

The processor 1308 may also be configured to access the display controller(s) 1328 over the system bus 1314 to control information sent to one or more displays 1332. The display controller(s) 1328 sends information to the display(s) 1332 to be displayed via one or more video processors 1334, which process the information to be displayed into a format suitable for the display(s) 1332. The display(s) 1332 can include any type of display, including, but not limited to, a cathode ray tube (CRT), a liquid crystal display (LCD), a plasma display, a light emitting diode (LED) display, etc. The display controller(s) 1328, display(s) 1332, and/or the video processor(s) 1334 can include an IC(s) 1304 that includes a MOL complementary power rail(s) coupled to a cell power rail(s) in the IC for reduced resistance, including but not limited to the ICs 300, 400, 500, 600, 1001, and 1201 in FIGS. 3A-6B, 10, and 12, and according to any aspects disclosed herein.

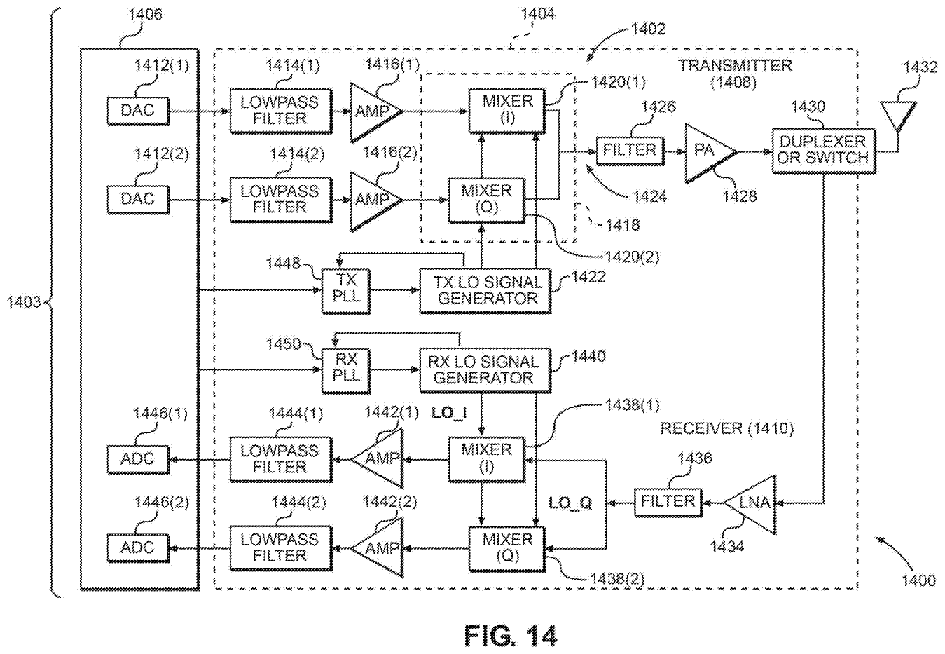

FIG. 14 illustrates an exemplary wireless communications device 1400 that includes radio frequency (RF) components formed from an IC(s) 1402 that include an IC(s) 1403 that includes a MOL complementary power rail(s) coupled to a cell power rail(s) in the IC for reduced resistance, including but not limited to the ICs 300, 400, 500, 600, 1001, and 1201 in FIGS. 3A-6B, 10 and 12, and according to any aspects disclosed herein, and according to any aspects disclosed herein. The wireless communications device 1400 may include or be provided in any of the above referenced devices, as examples. As shown in FIG. 14, the wireless communications device 1400 includes a transceiver 1404 and a data processor 1406. The data processor 1406 may include a memory to store data and program codes. The transceiver 1404 includes a transmitter 1408 and a receiver 1410 that support bi-directional communications. In general, the wireless communications device 1400 may include any number of transmitters 1408 and/or receivers 1410 for any number of communication systems and frequency bands. All or a portion of the transceiver 1404 may be implemented on one or more analog ICs, RF ICs (RFICs), mixed-signal ICs, etc.

The transmitter 1408 or the receiver 1410 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1410. In the direct-conversion architecture, a signal is frequency-converted between RF and baseband in one stage. The super-heterodyne and direct-conversion architectures may use different circuit blocks and/or have different requirements. In the wireless communications device 1400 in FIG. 14, the transmitter 1408 and the receiver 1410 are implemented with the direct-conversion architecture.

In the transmit path, the data processor 1406 processes data to be transmitted and provides I and Q analog output signals to the transmitter 1408. In the exemplary wireless communications device 1400, the data processor 1406 includes digital-to-analog converters (DACs) 1412(1), 1412(2) for converting digital signals generated by the data processor 1406 into the I and Q analog output signals, e.g., I and Q output currents, for further processing.

Within the transmitter 1408, lowpass filters 1414(1), 1414(2) filter the I and Q analog output signals, respectively, to remove undesired signals caused by the prior digital-to-analog conversion. Amplifiers (AMP) 1416(1), 1416(2) amplify the signals from the lowpass filters 1414(1), 1414(2), respectively, and provide I and Q baseband signals. An upconverter 1418 upconverts the I and Q baseband signals with I and Q transmit (TX) local oscillator (LO) signals through mixers 1420(1), 1420(2) from a TX LO signal generator 1422 to provide an upconverted signal 1424. A filter 1426 filters the upconverted signal 1424 to remove undesired signals caused by the frequency upconversion as well as noise in a receive frequency band. A power amplifier (PA) 1428 amplifies the upconverted signal 1424 from the filter 1426 to obtain the desired output power level and provides a transmit RF signal. The transmit RF signal is routed through a duplexer or switch 1430 and transmitted via an antenna 1432.

In the receive path, the antenna 1432 receives signals transmitted by base stations and provides a received RF signal, which is routed through the duplexer or switch 1430 and provided to a low noise amplifier (LNA) 1434. The duplexer or switch 1430 is designed to operate with a specific receive (RX)-to-TX duplexer frequency separation, such that RX signals are isolated from TX signals. The received RF signal is amplified by the LNA 1434 and filtered by a filter 1436 to obtain a desired RF input signal. Downconversion mixers 1438(1), 1438(2) mix the output of the filter 1436 with I and Q RX LO signals (i.e., LO_I and LO_Q) from an RX LO signal generator 1440 to generate I and Q baseband signals. The I and Q baseband signals are amplified by amplifiers (AMP) 1442(1), 1442(2) and further filtered by lowpass filters 1444(1), 1444(2) to obtain I and Q analog input signals, which are provided to the data processor 1406. In this example, the data processor 1406 includes ADCs 1446(1), 1446(2) for converting the analog input signals into digital signals to be further processed by the data processor 1406.

In the wireless communications device 1400 of FIG. 14, the TX LO signal generator 1422 generates the I and Q TX LO signals used for frequency upconversion, while the RX LO signal generator 1440 generates the I and Q RX LO signals used for frequency downconversion. Each LO signal is a periodic signal with a particular fundamental frequency. A TX phase-locked loop (PLL) circuit 1448 receives timing information from the data processor 1406 and generates a control signal used to adjust the frequency and/or phase of the TX LO signals from the TX LO signal generator 1422. Similarly, an RX PLL circuit 1450 receives timing information from the data processor 1406 and generates a control signal used to adjust the frequency and/or phase of the RX LO signals from the RX LO signal generator 1440.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. An integrated circuit (IC), comprising:
a front-end-of-line (FEOL) layer, comprising:
a diffusion region in a substrate;
at least one semiconductor channel structure in the diffusion region, the at least one semiconductor channel structure having a first longitudinal axis in a first direction;
a plurality of conducting gates disposed above the substrate, the plurality of gates each having a second longitudinal axis in a second direction substantially orthogonal to first longitudinal axis;
a Field-Effect Transistor (FET), comprising:
a semiconductor channel in a semiconductor channel structure among the at least one semiconductor channel structures;
an active gate in a portion of a conducting gate among the plurality of conducting gates adjacent to the semiconductor channel;
a source in a first end portion of the semiconductor channel; and
a drain in a second end portion of the semiconductor channel; and
a signal metal contact disposed above and in contact with one of the first active gate, the source, and the drain;
a back-end-of-line (BEOL) layer disposed above the FEOL layer, the BEOL layer comprising a metal interconnect layer comprising:
a cell power rail disposed in a first vertical access area and coupled to a supply voltage node configured to receive a supply voltage; and
a middle-of-line (MOL) layer disposed between the FEOL layer and the BEOL layer, the MOL layer comprising:
a power rail metal contact line in contact with the signal metal contact; and
a complementary power rail disposed in a second vertical access area;
the complementary power rail coupled to the power rail metal contact line and the cell power rail.

2. The IC of claim 1, wherein the second vertical access area of the complementary power rail vertically overlaps at least a portion of the first vertical access area of the cell power rail.

3. The IC of claim 1, wherein:
the cell power rail has a third longitudinal axis parallel to the first longitudinal axis and has a first length in the direction of the third longitudinal axis;
the power rail metal contact line has a fourth longitudinal axis in the second direction orthogonal to the second longitudinal axis; and
the complementary power rail has a fifth longitudinal axis parallel to the third longitudinal axis, and has a second length in the direction of the fifth longitudinal axis.

4. The IC of claim 3, wherein a ratio of the second length of the complementary power rail to the first length of the cell power rail is at least thirty percent (30%).

5. The IC of claim 1, wherein the cell power rail has a second width in the second direction, wherein a ratio of the second width to the first width is at least fifty percent (50%).

6. The IC of claim 1, wherein the complementary power rail comprises:
an elongated metal line in contact with the power rail metal contact line; and
a plurality of vias in contact with the elongated metal line and the cell power rail.

7. The IC of claim 6, wherein the elongated metal line has a second length in the first direction, wherein the second length is at least the first length of the cell power rail.

8. The IC of claim 1, wherein the complementary power rail comprises:
a metal line in contact with the power rail metal contact line; and
an elongated via in contact with the metal line and the cell power rail.

9. The IC of claim 8, wherein the elongated via has a second length in the first direction, and wherein the second length is at least the first length of the cell power rail.

10. The IC of claim 1, wherein the complementary power rail comprises:
an elongated metal line in contact with the power rail metal contact line; and
an elongated via in contact with the elongated metal line and the cell power rail.

11. The IC of claim 10, wherein the elongated metal line has a second length in the first direction, and wherein the second length is at least the first length of the cell power rail.

12. The IC of claim 10, wherein the elongated via has a second length in the first direction, and wherein the second length is at least the first length of the cell power rail.

13. The IC of claim 10, wherein the elongated metal contact line and the elongated via have a second length in the first direction, and wherein the second length is at least the first length of the cell power rail.

14. The IC of claim 1, wherein the complementary power rail comprises:
an elongated metal line in contact with the power rail metal contact line;
a plurality of vias in contact with the elongated metal line and the cell power rail; and
at least one via among the plurality of vias having a third length in the first direction, and at least one second via among the plurality of vias having a fourth length in the first direction;
the third length of the at least one via greater than the fourth length of the at least one second via.

15. The IC of claim 14, wherein the elongated metal line has a second length in the first direction, and wherein the second length is at least the first length of the cell power rail.

16. The IC of claim 1, wherein:
the cell power rail comprises:
a metal line comprising a first metal comprising a first resistivity; and
a first barrier layer surrounding the metal line, the first barrier layer having a first thickness; and
the signal metal contacts comprises:
a metal contact comprising a second metal having a second resistivity; and
a second barrier layer surrounding the metal contact, the second barrier layer having a second thickness;
wherein:
the first resistivity of the first metal is lower than the second resistivity of the second metal; and
the second thickness of the second barrier layer less than the first thickness of the first barrier layer.

17. The IC of claim 16, wherein:
the first metal comprises Copper (Cu); and
the second metal comprises at least one of Ruthenium (Ru) and Cobalt (Co).

18. The IC of claim 1, wherein the BEOL further comprises a second cell power rail coupled to a negative voltage node or ground node, the second cell power rail having a fourth longitudinal axis parallel to the third longitudinal axis in the first direction and having a second length along the fourth longitudinal axis in the first direction.

19. The IC of claim 1, wherein:
the diffusion region comprises:
a P-type diffusion region having a longitudinal axis disposed in the first direction;
an N-type diffusion region having a longitudinal axis disposed in the first direction substantially parallel to the longitudinal axis of the P-type diffusion region; and
the at least one semiconductor channel structure comprises at least one P-type semiconductor channel structure in the P-type diffusion region;
a non-diffusion region disposed along a fifth longitudinal axis between the P-type diffusion region and the N-type diffusion region;
the FET comprises a P-type FET (PFET), comprising:
the semiconductor channel comprising a P-type semiconductor channel in a P-type semiconductor channel structure among at least one P-type semiconductor channel structure;
the active gate adjacent to the P-type semiconductor channel;
a source in a first end portion of the P-type semiconductor channel; and
a drain in a second end portion of the P-type semiconductor channel; and
further comprising:
an N-type FET (NFET), comprising:
an N-type semiconductor channel in an N-type semiconductor channel structure among at least one N-type semiconductor channel structure;
a second active gate adjacent to the N-type semiconductor channel;
a second source in a first end portion of the N-type semiconductor channel; and
a second drain in a second end portion of the N-type semiconductor channel.

20. The IC of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

21. An integrated circuit (IC), comprising:
a front-end-of-line (FEOL) layer, comprising:
a means for providing a diffusion in a substrate;
a means for providing a semiconducting conduction path in the means for providing the diffusion;
a plurality of means for controlling the means for providing the semiconducting conduction path disposed above the substrate;
a Field-Effect Transistor (FET), comprising:
a semiconductor channel in the means for providing a semiconducting conduction path;
an active gate in a portion of the means for controlling the means for providing the semiconducting conduction path adjacent to the semiconductor channel;
a source in a first end portion of the semiconductor channel; and
a drain in a second end portion of the semiconductor channel; and
a means for providing a signal contact disposed above and in contact with one of the first active gate, the source, and the drain;
a back-end-of-line (BEOL) layer disposed above the FEOL layer, the BEOL layer comprising a metal interconnect layer comprising:
a means for providing a cell power node disposed in a first vertical access area and coupled to a supply voltage node configured to receive a supply voltage; and
a middle-of-line (MOL) layer disposed between the FEOL layer and the BEOL layer, the MOL layer comprising:
a means for providing a signal contact coupling in contact with the means for providing a signal contact; and
a complementary means for providing a cell power node disposed in a second vertical access area;
the complementary means for providing a cell power node coupled to the means for providing a signal contact coupling and the means for providing a cell power node.

22. A method of fabricating an integrated circuit (IC), comprising:
providing a front-end-of-line (FEOL) layer, comprising:
forming a diffusion region in a substrate;
forming at least one semiconductor channel structure in the diffusion region, the at least one semiconductor channel structure having a first longitudinal axis in a first direction;
forming a plurality of conducting gates disposed above the substrate, the plurality of gates each having a second longitudinal axis in a second direction substantially orthogonal to first longitudinal axis;
forming a Field-Effect Transistor (FET) in the diffusion region, comprising:
a semiconductor channel in a semiconductor channel structure among the at least one semiconductor channel structure;
an active gate in a portion of a conducting gate among the plurality of conducting gates adjacent to the semiconductor channel;
a source in a first end portion of the semiconductor channel; and
a drain in a second end portion of the semiconductor channel; and
forming a signal metal contact disposed above and in contact with one of the first active gate, the source, and the drain;
providing a back-end-of-line (BEOL) layer disposed above the FEOL layer comprising forming a metal interconnect layer comprising:
forming a cell power rail disposed in a first vertical access area and coupled to a supply voltage node configured to receive a supply voltage; and
providing a middle-of-line (MOL) layer disposed between the FEOL layer and the BEOL layer, comprising:
forming a power rail metal contact line in contact with the signal metal contact; and
forming a complementary power rail disposed in a second vertical access area;
the complementary power rail coupled to the power rail metal contact line and the cell power rail.

23. The method of claim 22, wherein:
forming the complementary power rail disposed in the second vertical access area of the MOL layer comprises:
forming a photoresist layer in the MOL layer;
disposing a mask over the first photoresist layer;
exposing the mask to form an opening in an interlayer dielectric (ILD) in the second vertical access area in the MOL layer;
etching a trench in the opening; and
filling the trench with a metal material to form the complementary power rail; and
forming the power rail metal contact line in contact with the signal metal contact comprises:
forming a second photoresist layer in the MOL layer;
disposing a second mask over the second photoresist layer;
exposing the second mask to form a second opening in an interlayer dielectric (ILD) in the MOL layer;
etching a second trench in the second opening; and
filling the second trench with a metal material to form the power rail metal contact line in contact with the complementary power rail.

24. The method of claim 22, wherein forming the complementary power rail disposed in the second vertical access area of the MOL layer and forming the power rail metal contact line in contact with the signal metal contact comprises:
forming a photoresist layer in the MOL layer;
disposing a mask over the first photoresist layer;
exposing the mask to form an opening in an interlayer dielectric (ILD) in second vertical access area in the MOL layer for the complementary power rail and for the power rail metal contact line;
etching a trench in the opening; and
filling the trench with a metal material to form the complementary power rail and the power rail metal contact line.

25. The method of claim 23, wherein forming the complementary power rail disposed in the second vertical access area comprises:
forming an elongated metal line in contact with the power rail metal contact line; and
forming a plurality of vias in contact with the elongated metal line and the cell power rail.

26. The method of claim 23, wherein forming the complementary power rail disposed in the second vertical access area comprises:
forming an elongated metal line in contact with the power rail metal contact line; and
forming an elongated via in contact with the elongated metal line and the cell power rail.

27. The method of claim 23, wherein forming the complementary power rail disposed in the second vertical access area comprises:
forming an elongated metal line in contact with the power rail metal contact line; and
forming an elongated via in contact with the elongated metal line and the cell power rail.

28. The method of claim 23, wherein forming the complementary power rail disposed in the second vertical access area comprises:
forming an elongated metal line in contact with the power rail metal contact line; and
forming a plurality of vias in contact with the elongated metal line and the cell power rail;
at least one via among the plurality of vias having a third length in the first direction, and at least one second via among the plurality of vias having a fourth length in the first direction;
the third length of the at least one via being greater than the fourth length of the at least one second via.

29. The method of claim 23, wherein:
forming the cell power rail comprises:
forming a metal line comprising a first metal comprising a first resistivity disposed in the first vertical access area and coupled to the supply voltage node configured to receive the supply voltage; and
forming a first barrier layer surrounding the metal line, the first barrier layer having a first thickness; and
forming the signal metal contact comprises:
forming a metal contact comprising a second metal having a second resistivity lower than the second resistivity of the second metal disposed above and in contact with one of the first active gate, the source, and the drain; and
forming a second barrier layer surrounding the metal contact, the second barrier layer having a second thickness less than the first thickness of the first barrier layer.

30. The method of claim 23, wherein:
forming the metal line of the cell power rail further comprises:
etching a trench in an interlayer dielectric (ILD) in the BEOL layer;
forming the first barrier layer in the trench; and
filling the trench with the first metal on the first barrier layer in the first trench; and
forming the metal contact of the signal metal contract further comprises:
etching a second trench in an interlayer dielectric (ILD) in the BEOL layer adjacent to the cell power rail;
forming the second barrier layer in the second trench, and
filling the second trench with the second metal on the second barrier layer in the second trench.

31. The method of claim 30, wherein:
forming the metal line of the cell power rail further comprises planarizing a top surface of the first metal with a top surface of the ILD; and
forming the metal contact of the signal metal contract further comprises planarizing a top surface of the second metal with a top surface of the ILD and the top surface of the first metal.
